(19) United States
(12) Patent Application Publication
(10) Pub. No.: US 2009/0114432 A1
(43) Pub. Date: May 7, 2009

(54) LAMINATE FOR PRINTED WIRING BOARD, PRINTED WIRING BOARD USING SAME, METHOD FOR MANUFACTURING PRINTED WIRING BOARD, ELECTRICAL COMPONENT, ELECTRONIC COMPONENT, AND ELECTRICAL DEVICE

(75) Inventor: Mitsuyuki Tsurumi, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Minato-ku, Tokyo (JP)

(21) Appl. No.: 12/092,922

(22) PCT Filed: Oct. 31, 2006
(86) PCT No.: PCT/JP2006/321752

§ 371 Date: May 7, 2008

(30) Foreign Application Priority Data
Nov. 7, 2005 (JP) 2005-322867

(51) Int. Cl. H05K 1/02; B32B 27/38; B32B 27/00; B32B 37/12

(52) U.S. Cl. 174/258; 428/413; 428/500; 156/273.3

(57) ABSTRACT

Disclosed is a laminate comprising, on a support: an insulating resin composition layer configured to produce a reactive active species when provided with energy; and a reactive polymer precursor layer containing a compound configured to react with the insulating resin composition layer and form a polymer compound.

### TECHNICAL FIELD

The present invention relates to a laminate suitably usable in manufacture of a printed wiring board, a printed wiring board manufactured using the same and a manufacturing method thereof, and also an electrical component, an electronic component and an electrical device which are provided with the printed wiring board. The present invention more particularly relates to: a printed wiring board with high-density wiring to be used in the field of electronic materials; a laminate for a printed wiring board which enables easy manufacture of a coppered laminate to be used in formation of the printed wiring board; a printed wiring board suitable for high-density mounting which is manufactured using the laminate; and a printed wiring board suitable for mounting and a method for manufacturing the same, and an electrical component, electronic component and electrical device equipped with circuit thereof.

### BACKGROUND ART

In recent years, with demands for increases in functionality of electronic devices and the like, increases in integration density of electronic components and increases in mounting density and the like have progressed, and reductions in size and increases in density of printed wiring boards and the like using the same that are suitable for high-density mounting have progressed. As responses to increases in density of these printed wiring boards and the like, various methods of realizing stable wiring with high-precision have been investigated, employing build-up multi-layer printed wiring boards and the like. However, there is a concern about build-up multi-layer printed wiring boards, in that when heat and pressure are applied to a layer between the multiple layers, a contact strength between layers which are connected by microscopic vias falls.

In formation of microscopic wiring, previously, a ‘subtractive process’ has been known as a metal pattern formation method which is useful in the field of conductive patterns, particularly printed wiring boards. A subtractive process is a method in which: a photosensitive layer, which is photosensitive to irradiation of active light rays, is provided on a metal layer formed on a substrate; the photosensitive layer is light-exposed pattern in an imagewise manner, and developed to form a resist image; then the metal is etched to form a metal pattern; and finally the resist is stripped away. At a metal substrate used in this procedure, in order to provide adhesiveness between the substrate and the metal layer, a substrate interface is processed for unevenness, and adhesiveness is realized by an anchoring effect. Hence, there is a problem in that substrate interface portions of the metallic pattern that is produced are uneven, and high frequency characteristics when this is used as electrical wiring are poor. Moreover, there is a problem in that a troublesome step is required for the unevenness processing of the substrate, meaning processing of the substrate with a strong acid such as chromic acid or the like.

In order to solve these problems, a method has been proposed for keeping unevenness of a substrate to a minimum and simplifying a step of processing of the substrate, by grafting a radical polymer compound to the substrate surface to improve the surface (see, for example, patent reference 1: the specification of Japanese Patent Application (Laid-Open) JP-A No. 58-196238). However, for this method, expensive equipment was required (a gamma ray generator, an electron beam generator).

In recent years, research into materials nanotechnology has attracted attention as a revolutionary technology for the 21st century. In particular, technologies for manufacturing films with nanoparticles accumulated and layered on surfaces have attracted attention as new materials technologies which can be exploited in a wide range of industrial fields, such as conductive films, optical films, biosensors, gas barrier films, and the like (see, for example, non-patent reference 1: Shipway, A. N. et al., Chem. Phys. Chem., vol. 1, p. 18 (2000) and non-patent reference 2: Templeton, A. C. et al. Acc. Chem. Res., vol. 33, p. 27 (2000)). In this research, in addition to the establishment of stable nanoparticle manufacturing processes in which size distributions, chemical compositions and the like are well-controlled, development of one-step processes which continuously perform thin film formation by accumulation, arrangement and deposition of manufactured nanoparticles on substrates are noted as being extremely important in practice. Heretofore, a method of laminating particles by multi-stage processing of microscopic particles (an alternating deposition process=LBL process) has been known as a technology for accumulating, arranging and depositing nanoparticles on a surface and fixing the nanoparticles (see, for example, non-patent reference 3: Brust, M. et al., D. J. Langmuir, vol. 14, p. 5452 (1998)). Systematic manufacture of multi-layer structures using these methods is possible. However, the steps are troublesome, and are not suitable as practical particle thin film formation procedures.

As one means for a fineparticle accumulation process, a method has been reported of using a surface graft polymer in which polymer ends are fixed to a substrate surface to accumulate gold nanoparticles at one level (see, for example, non-patent reference 5: Liz-Marzan, L. M. et al., J. Phys. Chem., vol. 99, p. 15120, (1995) and non-patent reference 6: Carignano, M. A. et al., Mol. Phys., vol. 100, p. 2993 (2002)). In this method, a polyacrylic amide brush fabricated on a glass surface is immersed overnight in a low-pH (approx. 6.5) dispersion of gold nanoparticles with negative charges. As a result, a film in which the nanoparticles are three-dimensionally accumulated is formed by electrostatic interaction of the positively charged amide groups (—CONH₃⁺) and the negatively charged nanoparticles. This method is much simpler than the LBL process. However, with a particle accumulation phenomenon caused by electrostatic forces of a charged polymer and charged particles in the conditions described here, interaction to an extent that is acceptable in practice is not formed, and a further improvement in conductive material adhesiveness in practice is desired.

Moreover, for forming such a surface graft polymer, a step of providing energy while causing components which are raw materials of the graft polymer to touch against a substrate surface is required. There is a problem in that uniform contact, and particularly maintaining uniformity in this step, which is carried out a number of times in a case of fabricating a multi-layer printed wiring board, is difficult.
Patent reference 1: the specification of JP-A No. 58-196238
Non-patent reference 1: Shipway, A. N. et al., Chem. Phys. Chem., vol. 1, p. 18 (2000)
Non-patent reference 2: Templeton, A. C. et al. Acc. Chem. Res., vol. 33, p. 27 (2000)
Non-patent reference 3: Brust, M. et al., D. J. Langmuir, vol. 14, p. 5452 (1998)
Non-patent reference 4: Bhat, R. R. et al., Nanotechnology, vol. 14, p. 1145, (2003)
Non-patent reference 5: Liz-Marzan, L. M. et al., J. Phys. Chem., vol. 99, p. 15120, (1995)
Non-patent reference 6: Carignano, M. A. et al., Mol. Phys., vol. 100, p. 2993 (2002)

### DISCLOSURE OF INVENTION

### Problem to be Solved by the Invention

An objective of the present invention, which has been made in consideration of the above-described problems of previous technologies, is to provide a laminate for a printed wiring board that is capable of easily forming, at an arbitrary solid surface, a conductive layer which is excellent in adhesiveness with an insulating film and of which unevenness at a interface with the insulating film is small.

Furthermore, another objective of the present invention is to provide a printed wiring board with high-precision wiring which is excellent in adhesiveness with an insulating layer, on a substrate formed using the laminate for a printed wiring board of the present invention, and a method for manufacturing the same.

### Means for Solving the Problem

The present inventor has discovered, as a result of earnest investigations, that it is possible to solve this problem with a laminate that includes a particular insulating resin composition layer and a polymer precursor layer capable of forming a graft polymer, and thus completed the invention.

That is, structures of the present invention are as described below.

<1> A laminate comprising, on a support: an insulating resin composition layer configured to produce a reactive active species when provided with energy; and a reactive polymer precursor layer containing a compound configured to react with the insulating resin composition layer and form a polymer compound.

<2> The laminate for a printed wiring board according to <1>, comprising the reactive polymer precursor layer and the insulating resin composition layer in this order on the support, and which is used for manufacturing a printed wiring board.

<3> The laminate for a printed wiring board according to <1>, comprising the insulating resin composition layer and the reactive polymer precursor layer in this order on the support, and which is used for manufacturing a printed wiring board.

<4> The laminate for a printed wiring board according to any one of <1> to <3>, comprising, at a surface of the laminate, a protective film that serves as a protective layer, and which may be used for manufacturing a printed wiring board.

<5> The laminate for a printed wiring board according to any one of <1> to <4>, wherein the reactive polymer precursor layer contains a compound with a functional group configured to react with the active species produced in the insulating resin composition layer and form a chemical bond when provided with energy, and which may be used for manufacturing a printed wiring board.

<6> The laminate according to any one of <1> to <5>, wherein the insulating resin composition layer contains a compound with a functional group configured to react with the reactive polymer precursor layer and form a chemical bond when provided with energy, and which may be used for manufacturing a printed wiring board.

<7> The laminate according to any one of <1> to <6>, wherein the reactive polymer precursor layer contains a compound with a polymerizable double bond, and which may be used for manufacturing a printed wiring board.

<8> The laminate for a printed wiring board according to <7>, wherein the insulating resin composition layer contains a compound configured to produce an active species that is configured to react with the compound with a polymerizable double bond contained in the reactive polymer precursor layer, when provided with energy.

<9> A method for manufacturing a printed wiring board, the method comprising: using the laminate according to any one of <1> to <8> and laminating such that the insulating resin composition layer and the reactive polymer precursor layer are disposed in this order on a substrate; thereafter, providing energy and thereby producing a polymer compound that directly bonds with the insulating resin composition layer and forming a polymer production region; and adhering a conductive material to the polymer production region.

<10> A printed wiring board formed by:

using the laminate according to any one of <1> to <8> and laminating such that the insulating resin composition layer and the reactive polymer precursor layer are disposed in this order on a substrate; thereafter, providing energy and thereby producing a polymer compound that directly bonds with the insulating resin composition layer and forming a polymer production region; and adhering a conductive material to the polymer production region.

<11> A method for manufacturing a printed wiring board comprising:

using the laminate according to any one of <1> to <8>, and laminating such that the insulating resin composition layer and the reactive polymer precursor layer are disposed in this order on a substrate; providing energy and producing a graft polymer layer that directly bonds with the insulating resin composition layer; and adhering a conductive material to a region of production of the graft polymer.

<12> A printed wiring board formed by: using the laminate for a printed wiring board according to any one of <1> to <8> and laminating such that the insulating resin composition layer and the reactive polymer precursor layer are disposed in this order on a substrate; thereafter, providing energy and producing a graft polymer layer that adheres with the insulating resin composition layer; and adhering a conductive material to a region of production of the graft polymer.

<13> A method for manufacturing a printed wiring board, comprising:

using the laminate for a printed wiring board according to any one of <1> to <8> and laminating such that the insulating resin composition layer and the reactive polymer precursor layer are disposed in this order on a substrate;

providing energy in a circuit pattern form and producing a graft polymer layer that directly bonds with the insulating resin composition layer in the circuit pattern form; and

adhering a conductive material to a region of production of the graft polymer and creating a direct circuit pattern.

<14> A printed wiring board comprising a circuit pattern provided by: using the laminate according to any one of <1> to <8> and laminating such that the insulating resin composition layer and the reactive polymer precursor layer are disposed in this order on a substrate; thereafter, providing energy in a circuit pattern form and producing a graft polymer layer that directly bonds with the insulating resin composition layer in the circuit pattern form; and adhering a conductive material to a region of production of the graft polymer.

<15> An electrical component, electronic component and electrical device employing, as a portion of a circuit, a printed wiring board manufactured by the method according to any one of <9>, <11> and <13> using the laminate for a printed wiring board according to any one of <1> to <8>.

By using the laminate for a printed wiring board of the present invention, it is possible to easily form a conductive layer which is excellent in adhesiveness with an insulating film on an arbitrary substrate or on wiring formed on an insulating film.

The laminate for a printed wiring board of the present invention can produce a final printed wiring board by a lamination step of adhering the laminate to an arbitrary solid surface such as a substrate or the like, a graft polymer formation step of light-exposing a region at which a conductive layer is to be formed and producing a graft polymer on the insulating film and, further, a conductive layer formation step of applying a conductive material to the graft polymer forming region and forming a conductive layer.

Further, by implementing provision of energy (light exposure) on the whole surface, it is possible to form the conductive material that is to form the conductive layer over the whole surface of the insulating material film surface, which is representative of a coppered laminate that is useful for formation of a printed wiring board or the like.

In this laminate, it is preferable if the insulating film is an insulating film that contains a polymerization initiator in an insulating resin, and it is preferable if the polymer precursor layer contains a compound with a polymerizable double bond that is capable of forming a graft polymer directly bonding to the insulating film surface when provided with energy.

### EFFECTS OF THE INVENTION

According to the present invention, it is possible to provide a laminate which is capable of easily forming, on an arbitrary solid surface, a conductive layer which is excellent in adhesiveness with an insulating film and has small unevenness at a interface with the insulating film, which laminate is useful in manufacture of a printed wiring board.

Further, by using the laminate for a printed wiring board of the present invention, it is possible to provide a printed wiring board including high-precision wiring which is excellent in adhesiveness with an insulating film, on a substrate, and various electronic devices and electrical devices that are equipped with such printed wiring boards as circuit.

A printed wiring board provided by the present invention has a fine wiring pattern which is excellent in high frequency characteristics, and can be suitably used in a multi-level wiring substrate.

### BRIEF DESCRIPTION OF THE DRAWINGS

FIG. 1 is schematic sectional diagrams showing steps (A) to (F) of forming a conductive layer over the whole of a desired package circuit substrate surface, using the laminate for a printed wiring board of the present invention.

FIG. 2 is schematic sectional diagrams showing steps (A)′ to (F)′ of forming a conductive layer in a pattern form on a portion of a desired package circuit substrate surface, using the laminate for a printed wiring board of the present invention.

### BEST MODE FOR CARRYING OUT THE INVENTION

The laminate for a printed wiring board of the present invention is characterized by including a support, for retaining the laminate, and at least two layers, meaning (A) a reactive polymer precursor layer capable of producing a polymer compound (a graft polymer) when provided with energy such as light-exposure or the like, and (B) an insulating resin composition layer at a surface of which the graft polymer can be produced.

In the present specification, ‘(A) the reactive polymer precursor layer’ may be referred to as ‘layer A’ or ‘the polymer precursor layer’ and ‘(B) the insulating resin composition layer’ may be referred to as ‘layer B’ or ‘the insulating layer’, respectively.

Herein, a protective layer is preferably provided at a surface of the laminate, for protecting the various functions of the support and the laminate including layer A and layer B, which are formed on the support, until a time of use.

A formation sequence of the reactive polymer precursor layer (A) and the insulating resin composition layer (B) is arbitrary. For example, a sequence with films of layer A and layer B in this order on the support is possible, and a sequence with layer B first on the support and with layer A thereon is possible.

Herein, ‘with a sequence’ for the present invention indicates that such layers are present on a substrate in the described order, but does not exclude the presence of other layers that are provided in accordance with requirements, such as, for example, an adhesive layer, a cushion layer and the like.

Below, the layers structuring the laminate for a printed wiring board of the present invention will be described in order.

(A) The Reactive Polymer Precursor Layer

The reactive polymer precursor layer contains at least one type of polymer precursor. The polymer precursor referred to here means a compound capable of producing a graft polymer when provided with energy such as light-exposure or the like (a polymer compound), or a compound that can form a cross-linking structure or suchlike with neighboring layers and improve adhesiveness of the two when provided with energy, or the like. Such a polymer precursor further has a functional group capable of interacting with a conductive material, which is a substructure to which the conductive material can be applied, as described later. Similar polymer precursors are included. A polymer compound (hereafter referred to where appropriate as a graft polymer) that is produced from a reactive compound by such a polymer precursor reacting is a compound to which the conductive material will be adhered. Therefore, for the polymer precursor, it is preferable to use a compound with both: a substructure that is capable of a polymerization reaction or cross-linking structure formation and is required for bonding with the insulating resin composition layer, for example, a ‘radical-polymerizable unsaturated double bond’ or the like; and a ‘functional group capable of interacting with the conductive material’, which is required for the later-described conductive material to be adhered to the graft polymer.

(Polymerizable Compound)

As typical examples among the polymer precursors described above, polymerizable compounds capable of a polymerization reaction can be mentioned. A polymerizable compound is a compound which includes radical-polymerizable unsaturated double bonds in the molecule.

As functional groups including a ‘radical-polymerizable unsaturated double bond’, vinyl groups, vinyloxy groups, allyl groups, acryloyl groups, methacryloyl groups and the like are mentioned. Of these, acryloyl groups and methacryloyl groups have high reactivity and provide excellent results.

As a radical-polymerizable unsaturated compound, any compound may be used provided the compound includes a radical-polymerizable group. For example, monomers including acrylate groups, methacrylate groups and vinyl groups, macromers, oligomers including polymerizable unsaturated groups, polymers and the like can be used.

Further, as other modes of the polymer precursor, the following are mentioned: oligomers or polymer compounds including reactive active groups within the molecule, for example, reactive active groups as represented by epoxy groups, isocyanate groups and azo groups, or the like; and combinations of cross-linking agents and cross-linkable compounds.

It is also required that the polymer precursor includes a functional group capable of interacting with a conductive material, which is a substructure to which the conductive material can be adhered.

For a functional group capable of interacting with a conductive material, a functional group with a positive charge, such as ammonium, phosphonium or the like, or a acidic group with a negative charge or capable of dissociating a negative charge, such as a sulfonic acid group, a carboxyl group, a phosphoric acid group, a phosphonic acid group or the like, are mentioned. Apart from these, non-ionic polar groups such as, for example, a hydroxyl group, an amide group, a sulfonamide group, an alkoxy group, a cyano group or the like can be used.

As a functional group with affinity with the conductive material, a hydrophilic group, a functional group capable of interacting with a electroless plating catalyst or a precursor thereof, and the like are mentioned.

If the polymer precursor which is a required component of ‘(A) the reactive polymer precursor layer’ relating to the present invention is described in detail taking a polymerizable compound, which is a representative case, as an example, it includes a radical-polymerizable unsaturated double bond, and the polymerizable compound that includes the functional group capable of interacting with the conductive material may be a low molecule and may be a high molecule. When it is a high molecule, the average molecular weight is selected in a range from 1,000 to 500,000. Such a high molecule is provided by a method of addition polymerization, polycondensation or the like of an ordinary radical polymer, anionic polymer or the like.

Specifically, in the present invention, as a compound which includes a radical-polymerizable unsaturated double bond (below referred to where appropriate as a polymerizable unsaturated bond group) and includes a functional group capable of interacting with a conductive material, hydrophilic polymers, hydrophilic macromers, hydrophilic monomers and the like that include hydrophilic groups, which are polar groups, are preferable in view of ease of adhesion/adsorption to metal ions or metal salts and ease of removal of non-reactants after a grafting reaction.

—Hydrophilic Monomers—

As specific examples of hydrophilic monomers that can be used for the present invention, the following monomers can be mentioned.

For example, the following can be used: (meth)acrylic acid or an alkali metal salt or amine salt thereof, itaconic acid or an alkali metal salt or amine salt thereof, allylamine or a hydrohalide salt thereof, 3-vinyl propionic acid or an alkali metal salt or amine salt thereof, vinyl sulfonic acid or an alkali metal salt or amine salt thereof, styrene sulfonic acid or an alkali metal salt or amine salt thereof, 2-sulfoethylene (meth)acrylate, 3-sulfo propylene (meth)acrylate or an alkali metal salt or amine salt thereof, 2-acrylamide-2-methyl propane sulfonic acid or an alkali metal salt or amine salt thereof, acid phosphoxy polyoxyethylene glycol mono(meth)acrylate or a salt thereof, 2-dimethylaminoethyl (meth)acrylate or a hydrohalide salt thereof, 3-trimethyl ammonium propyl (meth)acrylate, 3-trimethyl ammonium propyl (meth)acrylamide, N,N,N-trimethyl-N-(2-hydroxy-3-methacryloyl oxypropyl) ammonium chloride, and the like. Further, 2-hydroxyethyl (meth)acrylate, (meth)acrylamide, N-monomethylol (meth)acrylamide, N-dimethylol (meth)acrylamide, N-vinyl pyrrolidone, N-vinyl acetamide, polyoxyethylene glycol mono(meth)acrylate, and the like are useful.

—Hydrophilic Macromonomers—

For a manufacturing method of a macromonomer that is provided for use in the present invention, various manufacturing processes have been proposed in, for example, Chapter 2, “Synthesis of Macromonomers”, of Macromonomer Chemistry and Industry, edited by Yamashita Yuuya, published by IPC publishing, Sep. 20, 1989.

Particularly useful hydrophilic macromonomers that are provided for use in the present invention are: macromonomers derived from monomers including carboxyl groups such as acrylic acid, methacrylic acid and the like; sulfonic acid-based macromonomers derived from monomers such as 2-acrylamide-2-methyl propane sulfonic acid, vinyl styrene sulfonic acid, and salts thereof; amide-based macromonomers derived from monomers such as (meth)acrylamide, N-vinylacetamide, N-vinylformamide, and N-vinyl carboxylic amide; macromonomers derived from hydroxyl group-including monomers such as hydroxyethyl methacrylate, hydroxyethyl acrylate, glycerol monomethacrylate and the like; and macromonomers derived from alkoxy group-including or ethylene oxide group-including monomers such as methoxyethyl acrylate, methoxypolyethylene glycol acrylate, polyethylene glycol acrylate and the like. Further, a monomer with a polyethylene glycol chain or a polypropylene glycol chain can be usefully employed as a macromonomer of the present invention.

A molecular weight of a useful one of these hydrophilic macromonomers is in a range from 250 to 100,000, and a particularly preferable range is 400 to 30,000.

—Hydrophilic Polymers with a Polymerizable Unsaturated Group—

A hydrophilic polymer with a polymerizable unsaturated group means a radical-polymerizable group-including hydrophilic polymer in which an ethylene addition-polymerizable unsaturated group, such as a vinyl group, an allyl group, a (meth)acryl group or the like, has been introduced into the molecule. This radical-polymerizable group-including hydrophilic polymer should have the polymerizable group at the end of a main chain and/or in a side chain, and preferably has the polymerizable groups in both. Herebelow, the hydrophilic polymer with polymerizable groups (at the main chain end and/or in the side chain) will be referred to as the radical-polymerizable group-including hydrophilic polymer.

Such a radical-polymerizable group-including hydrophilic polymer can be synthesized as follows. Synthesis methods that are mentioned are: (a) a method of copolymerizing a hydrophilic monomer with a monomer including an ethylene addition-polymerizable unsaturated group; (b) a method of copolymerizing a hydrophilic monomer with a monomer including a double bond precursor and then introducing the double bond by processing with a base or the like; and (c) a method of reacting a functional group of a hydrophilic polymer with a monomer including an ethylene addition-polymerizable unsaturated group. Among these, (c) the method of reacting a functional group of a hydrophilic polymer with a monomer including an ethylene addition-polymerizable unsaturated group is particularly preferable in regard to synthesis suitability.

In the above methods (a) and (b), for a hydrophilic monomer that is used for synthesis of the radical-polymerizable group-including hydrophilic monomer, monomers including a hydrophilic group such as a carboxyl group, sulfonic acid group, phosphoric acid group, amino acid group or a salt thereof, or a hydroxyl group, an amide group, an ether group or the like, are mentioned, such as: (meth)acrylic acid or an alkali metal salt or amine salt thereof, itaconic acid or an alkali metal salt or amine salt thereof, 2-hydroxyethyl (meth)acrylate, (meth)acrylamide, N-monomethylol (meth)acrylamide, N-dimethylol (meth)acrylamide, allylamine or a hydrohalide salt thereof, 3-vinyl propionic acid or an alkali metal salt or amine salt thereof, vinyl sulfonic acid or an alkali metal salt or amine salt thereof, 2-sulfoethyl (meth)acrylate, polyoxyethylene glycol mono(meth)acrylate, 2-acrylamide-2-methyl propane sulfonic acid, acid phosphoxy polyoxyethylene glycol mono(meth)acrylate, and the like.

As a hydrophilic monomer to be used in method (c), a hydrophilic homopolymer or copolymer obtained using at least one type selected from these hydrophilic monomers is used.

When synthesizing the radical-polymerizable group-including hydrophilic polymer with method (a), as the monomer including an ethylene addition-polymerizable unsaturated group that is to be copolymerized with the hydrophilic monomer, there are, for example, allyl group-including monomers, and specifically, allyl (meth)acrylate and 2-allyloxyethyl methacrylate are mentioned. When synthesizing the radical-polymerizable group-including hydrophilic polymer with method (b), as the monomer including a double bond precursor that is to be copolymerized with the hydrophilic monomer, 2-(3-chloro-1-oxopropoxy)ethyl methacrylate is mentioned. Further, when synthesizing the radical-polymerizable group-including hydrophilic polymer with method (c), it is preferable to introduce the unsaturated group by utilizing a reaction of a carboxyl group or amino group or salt thereof in the hydrophilic polymer with a functional group such as a hydroxyl group, epoxy group or the like. As the monomer including an addition-polymerizable unsaturated group that is to be used for this, (meth)acrylic acid, glycidyl (meth)acrylate, allyl glycidyl ether, 2-isocyanato ethyl (meth)acrylate or the like is mentioned.

If a macromonomer or polymer is used as the polymerizable compound, it is easy to prepare a liquid composition containing the polymerizable compound with a suitable viscosity for forming a layer by a coating process. In the laminate of the present invention, the reactive polymer precursor layer (A) can be easily formed on the support or on the later-described insulating resin composition layer (B) by coating and drying this liquid composition.

On the other hand, if a hydrophilic monomer is used as the polymer compound, it is preferable to use a binder and the like for forming a stable coating film at the reactive polymer precursor layer (A), or it is preferable to cover a low-viscosity coating film formed of a liquid composition with a protective layer, which will be described in detail later, to achieve stabilization of layer A.

Given this, when a macromonomer or polymer is employed as the polymer precursor, the reactive polymer precursor layer (A) can be easily formed with a uniform film thickness, and hence it is understood that a uniform graft polymer forming region is formed. Therefore, when a macromonomer or polymer is used as the polymerizable compound to form the laminate of the present invention, by use of this laminate, a printed wiring board can be obtained at which a conductive layer which is excellent in conductivity and also excellent in uniformity has been formed by a simple method.

As described above, with regard to fabrication characteristics, it is most preferable to use a macromonomer or polymer as the polymerizable compound, coat and dry a solution thereof at the surface of an insulating film formed of, for example, epoxy resin or the like, and form (A) the reactive polymer precursor layer.

The polymer precursor represented by these polymerizable compounds is preferably contained to around 5 to 100% by weight of total solids forming layer A, and a range of 30 to 100% by weight is more preferable.

(Other Components Usable in the Polymer Precursor Layer)

The polymer precursor layer (A) may contain, in addition to the above-described polymerizable compound, various compounds in accordance with objectives such as, for example, a binder for improving film characteristics, a plasticizer, a surfactant, a viscosity regulator and the like, provided the effects of the present invention are not impeded.

(Binder)

A binder is employed for forming the polymer precursor layer (A) with the radical-polymerizable group-including hydrophilic compound, and is useful for improving film characteristics. If the polymerizable compound can form the layer by itself, a binder is not particularly necessary, but inclusion is preferable with a view to improving layer formation characteristics for employing a low-viscosity monomer as the polymerizable compound. A binder for this purpose is mixed with the polymerizable group-including hydrophilic compound, and is not particularly limited as long as it forms the film, but oligomers and polymers with molecular weight at least 500 and water solubility are preferable.

As such polymers, besides synthetic polymers such as (meth)acrylate-based polymers, cellulose-based polymers and the like, such as polyacrylic acid, polymethacrylic acid, polyvinyl alcohol, polybutyral, polyvinyl pyrrolidone, polyethylene oxide, polyethylene imine, polyacrylamide, carboxymethyl cellulose, hydroxyethyl cellulose and the like, natural hydrophilic polymers such as gelatin, starch, gum arabic, sugar and the like can be employed.

When a binder is used, an inclusion amount is preferably from 0 to 95% by weight of solid content equivalents, and more preferably in a range from 0 to 70% by weight.

(Plasticizer, Surfactant and Viscosity Regulator)

These compounds are employed for improving coating surface characteristics when forming a covering of the reactive polymer precursor layer (A), or providing flexibility to the covering film, and suppressing occurrences of cracking when a film condition is curved or the like. Publically known materials which are commonly used as plasticizers, surfactants and viscosity regulators are employed.

(Formation of Reactive Polymer Precursor Layer)

The reactive polymer precursor layer (A) is formed by dissolving the above-described components in a suitable solvent to prepare a coating liquid, coating the coating liquid onto the support or onto the later-described insulating layer (B), and drying.

As the solvent, water or an organic solvent is employed. Both hydrophilic solvents and hydrophobic solvents can be employed as an organic solvent, and in particular solvents with high affinity to water are useful. Specifically, alcohol-based solvents such as methanol, ethanol, 1-methoxy-2-propanol and the like, ketone-based solvents such as acetone, methylethyl ketone and the like, ether-based solvents such as tetrahydrofuran and the like, and nitrile-based solvents such as acetonitrile and the like are preferable.

A solid component concentration of the coating liquid is preferably 0.1/80% by weight.

Coating is performed by a usual process. Publicly known coating methods such as, for example, a blade coating process, a rod coating process, a squeeze coating process, a reverse roller coating process, a transfer roller coating process, a spin-coating process, a bar coating process, an air-knife process, a gravure printing process, a spray coating process and the like are mentioned.

A thickness of the reactive polymer precursor layer is preferably in a range from 0.5 μm to 10 μm. In this range, a thickness of a graft polymer layer that is formed subsequently will be in a suitable range, and in subsequent steps, for example, when adhering the conductive material, excellent adhesiveness with the conductive material can be assured.

The thickness of the graft polymer layer that is produced when provided with energy such as light-exposure or the like, after formation of the polymer precursor layer, is preferably in a range from 0.1 μm to 4.0 μm. Accordingly, the more the thickness of the polymer precursor layer is thicker than 10 μm, the more material will not contribute to formation of the graft polymer, and in addition to leading to increases in costs, this will cause many problems, such as an exposure light source that reaches to deeper portions being more difficult, removal of non-required graft polymer precursor material being more difficult, and the like.

(B) Insulating resin Composition Layer

For formation of the insulating resin composition layer of the present invention, publicly known insulating resins which have come to be used heretofore as multi-layer laminated boards, build-up substrates and flexible substrates can be used. These resins are formed of thermosetting resins, thermoplastic resins, and resin mixtures thereof. For the present invention, these resins can be used as is, but it is preferable to use these insulating resins with a polymerization initiator included therein with a view to easily causing a grafting reaction with the reactive polymer precursor layer (A) that is provided proximately. Furthermore, with the objective of raising graft reactivity or strength of the insulating resin, a multi-functional acrylate monomer may be added. As other components, inorganic or organic particles may be added, for raising strength of the insulating layer or improving electrical characteristics. Herein, the insulating resin of the present invention means a resin having insulation properties to an extent that is usable for publicly known insulating films, even it may not be a complete insulator, and it may be employed in the present invention as long as it is a resin having insulation properties in accordance with objectives.

Herebelow, various components used in an insulating resin composition layer that is usable for the present invention will be described in order.

As specific examples of thermosetting resins usable in the insulating resin composition layer (B) relating to the present invention, for example, epoxy resins, phenol resins, polyimide resins, polyester resins, bismaleimide resins, polyolefin-based resins, isocyanate-based resins and the like are mentioned.

As epoxy resins, for example, cresol novolac-type epoxy resins, bisphenol A-type epoxy resins, bisphenol F-type epoxy resins, phenol novolac-type epoxy resins, alkyl phenol novolac-type epoxy resins, biphenol F-type epoxy resins, naphthalene-type epoxy resins, dicyclopentadiene-type epoxy resins, an epoxy compound of a condensate of a phenol with an aromatic aldehyde including phenolic hydroxyl groups, triglicidyl isocyanurate, alicyclic epoxy resins and the like are mentioned. These may be used individually, or two or more types may be used. Thus, heat endurance and the like will be excellent.

As polyolefin-based resins, for example, polyethylene, polystyrene, polypropylene, polyisobutylene, polybutadiene, polyisoprene, cycloolefin-based resins, copolymers of these resins, and the like are mentioned.

These epoxy resins will be described in further detail.

An epoxy resin to constitute the insulating resin composition layer (B) of the present invention is formed of a reaction product between (a) an epoxy compound with two or more epoxy groups in one molecule and (b) a compound with two or more functional groups in one molecule that react with the epoxy groups. The functional groups of (b) are selected from functional groups such as carboxyl groups, hydroxyl groups, amino groups, thiol groups and the like.

As an epoxy compound (a) with two or more epoxy groups in one molecule (including compounds referred to as epoxy resins), epoxy compounds that include 2 to 50 epoxy groups in one molecule are preferable, and epoxy compounds that include 2 to 20 epoxy groups in one molecule are more preferable. Here, it is sufficient if the epoxy groups are structures with oxilane ring structures and, for example, glycidyl groups, oxyethylene groups, epoxy cyclohexyl groups and the like can be noted. Such polyvalent epoxy groups are widely disclosed, for example, in Epoxy Resin Handbook, edited by M. Shinbo, published by Nippan Kogyo Shinbunsha (1985), and the like, and these can be utilized.

Specifically, the following can be mentioned: bisphenol A-type epoxy resins, bisphenol F-type epoxy resins, bromide bisphenol A-type epoxy resins, bisphenol S-type epoxy resins, diphenyl ether-type epoxy resins, hydroquinone-type epoxy resins, naphthalene-type epoxy resins, biphenyl-type epoxy resins, fluorene-type epoxy resins, phenol novolac-type epoxy resins, orthocresol novolac-type epoxy resins, tris-hydroxy phenyl methane-type epoxy resins, 3-function-type epoxy resins, tetraphenylol ethane-type epoxy resins, dicyclopentadienephenol-type epoxy resins, hydrogenated bisphenol A-type epoxy resins, bisphenol A including nucleic polyol-type epoxy resins, polypropylene glycol-type epoxy resins, glycidyl ester-type epoxy resins, glycidyl amine-type epoxy resins, glyoxal-type epoxy resins, alicyclic epoxy resins, heterocyclic epoxy resins, and the like.

As the compound (b) with two or more functional groups in one molecule that react with epoxy groups, multi-functional carboxylate compounds such as terephthalic acid and the like, multi-functional hydroxy compounds such as phenol resins and the like, amino resins, and multi-functional amino compounds such as 1,3,5-triaminotriazine and the like can be mentioned.

An epoxy resin curing agent may be included in the resin composition of the present invention. For example, there are multi-functional phenols, amines, imidazole compounds, acid anhydrides, organic phosphorus compounds, halides of these, and the like, but it is preferable to utilize one that does not impede a chemical reaction with the polymer precursor layer. Further, in the insulating resin composition of the present invention, as necessary, a curing accelerator may be mixed in. As representative curing accelerators, there are tertiary amines, imidazoles, quaternary ammonium salts and the like, but these are not particularly limiting.

As a thermoplastic resin, for example, phenoxy resins, polyether sulfone, polysulfone, polyphenylene sulfone, polyphenylene sulfide, polyphenyl ether, polyether imide and the like are mentioned. As other thermoplastic resins, there are: (1) 1,2-bis(vinylphenylene)ethane resin (1,2-bis(vinylphenyl)ethane) or a modified resin of the same with a polyphenylene ether resin (described by S. Amou et al., Journal of Applied Polymer Science, vol. 92, 1252-1258 (2004)); (2) liquid crystal polymers, specifically VECSTAR, produced by KURARAY, and the like; and (3) fluoride resins (PTFE), and the like.

(Mixture of Thermoplastic Resin and Thermosetting Resin)

A thermoplastic resin and a thermosetting resin may each be used individually, or two or more types may be used together. This is implemented with the objective of realizing excellent results by compensating for the deficiencies of each. For example, because a thermoplastic resin such as polyphenylene ether (PPE) or the like has low resistance to heat, alloying with a thermosetting resin or the like is implemented. For example, it may be employed as an alloy of PPE with an epoxy and triallyl isocyanate, or as an alloy of a PPE resin into which a polymerizable functional group has been introduced with another thermosetting resin. A cyanate ester is a resin which is most excellent in dielectric characteristics among thermosetting characteristics, but using this alone is less often, and it will be employed as a modified resin of an epoxy resin, a maleimide resin, a thermoplastic resin or the like. These are described in detail in Electronic Technology, 2002/issue 9, p. 35. Thus, a resin including an epoxy resin and/or a phenol resin as a thermosetting resin, and including a phenoxy resin and/or polyether sulfone (PES) as a thermoplastic resin, is employed in order to improve dielectric characteristics.

(Compound Including Polymerizable Double Bonds)

Required compounds can be added into the insulating layer in accordance with application objectives. As such a compound, there is a compound that includes a radical-polymerizable double bond. A compound including a radical-polymerizable double bond is an acrylate or methacrylate compound. An acrylate compound ((meth)acrylate) usable in the present invention is not particularly limited as long as it is a compound with an acryloyl group, which is an ethylenically unsaturated group, in the molecule. However, multi-functional monomers are preferable in regard to curing characteristics, hardness of an intermediate layer that is formed, and strength improvement.

As a multi-functional monomer that is usable in application to the present invention, esters of polyvalent alcohols and acrylic acid or methacrylic acid are preferable. Examples of polyvalent alcohols include ethylene glycol, 1,4-cyclohexanol, pentaerythritol, trimethylol propane, trimethylol ethane, dipentaerythritol, 1,2,4-cyclohexanol, polyurethane polyol and polyester polyol. Of these, trimethylol propane, pentaerythritol, dipentaerythritol and polyurethane polyol are more preferable. Two or more types of multi-functional monomer may be included in the intermediate layer. The multi-functional monomer is indicated as being one that includes at least two ethylenically unsaturated groups in the molecule, but one that includes three or more is preferable. Specifically, multi-functional acrylate monomers with three to six acrylic acid ester groups in the molecule are mentioned. Further, oligomers including a number of acrylic acid ester groups in a molecule with a molecular weight from hundreds to thousands, referred to as urethane acrylate, polyester acrylate and epoxy acrylate, can also be preferably employed as a component of an intermediate layer of the present invention.

As specific examples of these acrylates with three or more acryl groups in the molecule, the following can be mentioned: polyol polyacrylates such as trimethylol propane triacrylate, ditrimethylol propane tetraacrylate, pentaerithrytol triacrylate, pentaerithrytol tetraacrylate, dipentaerithrytol pentaacrylate, dipentaerithrytol hexacrylate and the like; urethane acrylates obtained by reaction of a polyisocyanate with a hydroxyl group-including acrylate such as hydroxyethyl acrylate or the like; and the like. In addition, as a compound that includes polymerizable double bonds, a resin in which a portion of the resin has been subjected to a (meth)acrylation reaction may be used: using methacrylic acid, acrylic acid or the like on a thermosetting resin or thermoplastic resin, for example, an epoxy resin, a phenol resin, a polyimide resin, a polyolefin resin, a fluoride resin or the like. Specifically, (meth)acrylate compounds of epoxy resins can be mentioned.

These insulating resins are preferably 5 to 100% by weight of solid content equivalents in the composition for forming the insulating resin composition layer.

(Type of Polymerization Initiator Added to the Insulating Resin Composition Layer)

For a polymerization initiator usable in the insulating resin composition layer (B) of the present invention, thermal polymerization initiators and photopolymerization initiators can both be employed. As a thermal polymerization initiator, peroxide initiators, azo-based initiators and the like, such as benzoyl peroxide, azoisobutyronitrile and the like can be employed. As photopolymerization initiators, generally publicly known initiators can be employed, and may be low molecules and may be high molecules.

As low-molecule photopolymerization initiators, for example, publicly known radical generators such as the following can be employed: acetophenones, benzophenones, Michler's ketone, benzoyl benzoate, benzoins, α-acyloxime ester, tetramethyl thiuram monosulfide, trichloromethyl triazine, thioxantone and the like. Ordinarily, sulfonium salts, iodinium salts and the like that are used as photo-acid generating agent can also be utilized as radical generators when irradiated, and therefore these may be used for the present invention. Further, sensitizer may be used to sensitize and may be used in addition to a photoradical-polymerization initiator with the objective of raising sensitivity. Examples of sensitizers include n-butylamine, triethylamine, tri-n-butylphosphine, thioxantone derivatives, and the like.

As high-molecule light radical generators, polymer compounds with active carbonyl groups in side chains, described in Japanese Patent Application Laid-Open (JP-A) No. 9-77891 and JP-A No. 10-45927, can be employed.

The amount of a polymerization initiator included in the insulating resin is selected in accordance with an application of the surface graft material that is employed, but will ordinarily preferably be around 0.1 to 50% by weight of solid components in the insulator layer, more preferably being around 1.0 to 30.0% by weight.

(Other Additives Included in the Insulating resin Composition Layer)

In layer B of the present invention, in order to enhance characteristics such as mechanical strength, heat resistance, weather resistance, fireproofing, water resistance, electrical characteristics and the like of the resin film, a composite of the resin and other components (a composite material) can be employed. As a material to be employed for composition, paper, glass fiber, silica particles, phenol resin, polyimide resin, bismaleimide triazine resin, fluoride resin, polyphenylene oxide resin and the like can be mentioned.

Furthermore, depending on requirements, a filler that is used in resin materials for wiring boards may be mixed into the insulating resin composition, for example, one type or two or more types of inorganic fillers such as silica, alumina, clay, talc, aluminium hydroxide, calcium carbonate and the like and inorganic fillers such as cured epoxy resins, crosslinked benzoguanamine resins, cross-linked acryl polymers and the like.

Depending on requirements, one type or two or more types of various additives may also be added to this insulating resin composition, such as a coloring agent, a fireproofing agent, an adhesion-enhancing agent, a silane-coupling agent, an antioxidant, an ultraviolet absorber and the like.

When such materials are added, each is preferably added in a range from 1 to 200% by weight relative to the resin, and is more preferably added in a range from 10 to 80% by weight. If such an addition amount is less than 1% by weight, there will be no strong effect of the above-mentioned characteristics, and if it exceeds 200% by weight, characteristics such as strength and the like of the resin itself will fall, in addition to which the graft polymer reaction will not progress.

(Form of Insulating Resin Composition Layer)

A thickness of the insulating film of the present invention will generally be in a range from 1 μm to 10 mm, and will preferably be in a range from 10 μm to 1000 μm.

With a view to improving characteristics of the conductive layer that is formed, for the insulating film formed from the insulating resin it is preferable to use a film with an average roughness (Rz), measured by the 10-point average height method, JIS B 0601 (1994), of 3 μm or less, and Rz is more preferably 1 μm or less. This will be excellent to use when structuring a printed wiring board with an extremely fine circuit (for example, a circuit pattern with lines/spaces of 25/25 μm or less), provided a surface smoothness of the substrate is within a range of the above-described values, that is, is in a state with substantially no unevenness.

Further, in a similar regard, when the laminate of the present invention is to be used to form wiring on a substrate, smoothness of the substrate that is used is also preferably in the above-described ranges.

(Formation of (B) Insulating resin Composition Layer)

For layer (B), the above-described components are dissolved in a suitable solvent or formed into a varnish. Hence, a coating liquid prepared so as to improve coating characteristics is coated onto the support or onto the earlier-described polymer precursor layer (A), and dried, and thus a film for forming the insulating film is formed. Because the film for forming the insulating film is formed as a film, thickness accuracy is higher, handling characteristics, positioning accuracy and the like are improved, and it can be excellently used as an insulating film, an adhesion film and the like for various electronic components.

An ordinary organic solvent is employed as the solvent. For an organic solvent, any hydrophilic solvent or hydrophobic solvent may be employed, but a solvent that dissolves a thermosetting resin and thermoplastic resin that will form the insulating resin composition layer and a polymer precursor that will form the resin after reaction is useful. Specifically, alcohol-based solvents such as methanol, ethanol, 1-methoxy-2-propanol and the like, ketone-based solvents such as acetone, methylethyl ketone and the like, ether-based solvents such as tetrahydrofuran and the like, and nitrile-based solvents such as acetonitrile and the like are preferable. Further, N-methyl-2-pyrrolidone, N,N-dimethyl acetamide, N,N-dimethyl formamide, ethylene glycol monomethyl ether, tetrahydrofuran and the like can be employed.

With regard to viscosity and workability of the coating liquid or varnish, coating workability, drying duration and working efficiency, a mixture quantity of the solvent for forming the coating liquid or varnish is preferably 5 to 2000 parts by weight for 100 parts by weight of the insulating resin composition, and is more preferably from 10 to 900 parts by weight.

As a method for preparing a varnish of the resin composition, publically known methods can be used for preparation, such as a mixer, a bead mill, a pearl mill, a kneader, a triple roller or the like. The various mixture components may be added at the same time, or an addition sequence may be suitably specified, or, as necessary, some of the mixture components may be pre-kneaded beforehand and then added.

Coating onto the support for forming the film is carried out by a usual process. For example, publicly known coating methods are mentioned, such as a blade coating process, a rod coating process, a squeeze coating process, a reverse roller coating process, a transfer roller coating process, a spin-coating process, a bar coating process, an air-knife process, a gravure printing process, a spray coating process and the like.

A method for removal of the solvent is not particularly limited, but implementation by evaporation of the solvent is preferable. As a method for evaporating the solvent, methods such as heating, pressure reduction, air-blowing and the like are considered. Among these, evaporation by heating is preferable with regard to productivity and handling characteristics, and evaporation by heating while blowing air is more preferable. For example, it is preferable to perform a coating process at one face of the support, which will be described next, heat and dry at 80° C. to 200° C. for 0.5 minutes to 10 minutes to remove the solvent, and thus form the film in a state in which there is no stickiness in a semi-cured condition.

(Support)

The laminate for a printed wiring board of the present invention includes a support that acts as a base film, and at least layer (A) and layer (B) between the support and a later-described protective layer. The support is employed as a base of the laminate for a duration until the laminate of the present invention is touched against a predetermined substrate or the like and employed in formation of the printed wiring board.

As a base film usable for the support, the following are suggested: a resin sheet of a polyolefin such as polyethylene, polypropylene, polyvinyl chloride or the like, a polyester such as polyethylene terephthalate or the like, a polyamide, a polyimide, a polycarbonate or the like; a release paper or the like; a processing paper with controlled surface adhesiveness; a metal foil such as a copper foil or aluminium foil; or the like.

As a thickness of the support, 2 to 200 μm will be common, but 5 to 50 μm is more preferable, and 10 to 30 μm is even more preferable. If a sheet used as the support is too thick, when wiring is formed in practice using this laminate, in particular, when laminating the laminate onto a predetermined substrate or onto wiring, problems will arise with handling characteristics and the like.

Here, besides matt processing and corona processing, releasing processing may be conducted on a surface of a sheet that structures the support.

By making a width of the support around 5 mm longer than a width of the insulating film or the polymer precursor layer, when performing lamination with another layer, adhesion of resin at lamination portions can be prevented, and an advantage in that peeling of the support base film at a time of employment is easier is provided.

(Adhesion Layer and Cushion Layer)

When forming the laminate for a printed wiring board of the present invention, in order to improve adhesiveness between the support and another layer that is formed adjacently, or in order to improve cushioning during lamination so as to improve adhesion: after the resin varnish dissolved in the predetermined organic solvent is coated at the surface of the base film that acts as the support, the solvent is dried by heating and/or hot air-blowing, a resin composition that is solid at usual temperatures is formed, and an adhesion agent layer or cushion layer can be prepared.

Here, as the organic solvent that is used in application of the resin varnish, usual solvents can be employed, alone or in a combination of two or more types; for example, ketones such as acetone, methylethyl ketone, cyclohexanone and the like, acetic esters such as ethyl acetate, butyl acetate, cellosolve acetate, propylene glycol monomethyl ether acetate, carbitol acetate and the like, cellosolves such as cellosolve, butyl cellosolve and the like, carbitols such as carbitol, butyl carbitol and the like, aromatic hydrocarbons such as toluene, xylene and the like, and also dimethyl formamide, dimethyl acetamide, N-methyl-pyrrolidone, and the like.

(Protective Layer)

As a resin film that forms the protective layer, the same material as that used for the support may be used, or a different material may be used. As materials that are suitably employed, similarly to the support, the following can be mentioned: a resin sheet of a polyolefin such as polyethylene, polyvinyl chloride, polypropylene or the like, a polyester such as polyethylene terephthalate or the like, a polyamide, a polycarbonate or the like; a release paper or the like; a processing paper with controlled surface adhesiveness; a metal foil such as a copper foil or aluminium foil; or the like.

As a thickness of the protective layer (protective film), 2 to 150 μm will be common but 5 to 70 μm will be more preferable, and 10 to 50 μm even more preferable. Of the thickness of the protective film and the thickness of the support base film, either may be thicker than the other.

Besides matt processing and corona processing, releasing processing may be conducted on the protective film.

The laminate for a printed wiring board of the present invention that is obtained by laminating these layers is further laminated with this protective film, and, for example, is wound up into a roll and stored.

(Manufacture of the Laminate for a Printed Wiring Board)

The laminate for a printed wiring board of the present invention is formed by, first, providing the insulating resin composition layer (B) which is formed to include a polymerization initiator in the insulating resin on the support, then forming the polymer precursor layer (A), and covering the polymer precursor layer (A) with the protective layer, or alternatively, forming the polymer precursor layer (A) on the support, then forming the insulating resin composition layer (B), and covering the surface with the protective layer. Furthermore, an adhesion layer may be provided between the support and the polymer precursor layer (A) or between the polymer precursor layer (A) and the insulating resin composition layer (B).

Thus, the laminate for a printed wiring board of the present invention is provided.

For the laminate of the present invention, the following are major features: a polymerization initiator is contained in the insulating resin, such as an epoxy resin, polyimide resin, liquid crystal resin, polyarylene resin or the like, at the surface of the support; and an initiator-containing insulator layer is provided and the polymer precursor layer is provided adjacent thereto. Hence, by this laminate being deployed at a surface of an arbitrary substrate or wiring and energy being provided, an insulator layer with required characteristics and a graft polymer forming region which is directly bonded to a surface of this insulating layer can be formed. Because this graft polymer is excellent in affinity with the conductive material, by using the laminate for a printed wiring board of the present invention, a smooth and uniform conductive film can be formed at a desired region in accordance with energy provision.

In the present invention, adhesion between the insulating layer and the graft is further secured by the inclusion of the polymerization initiator in the insulating resin, and strong adhesion is expressed.

A reason therefor is not clear, but it is thought that it can be thought that a surface graft density is increased by adding the polymerization initiator to the insulating resin, interaction with the conductive material layer is further raised, and as a result, adhesion is improved.

Further, this technology is a wide-ranging technology which can also be applied to common insulating resins that are useful in the field of electronic materials, such as polyimides, epoxy resins and the like.

(Manufacture of Printed Wiring Board Using the Laminate for a Printed Wiring Board)

The protective film is peeled off and the laminate of the present invention is adhered to an arbitrary solid surface. Then, the support is peeled off, or if the support can pass a light source of exposure light for energy provision, a desired region is exposed as is. Thus, at the exposed region, the polymerizable compound in the polymer precursor layer (A), with active site generated from the initiator in the insulating film (B) as base points, forms strong chemical bonds at the insulating film/precursor layer interface, and the graft polymer is formed. Thereafter, the polymer precursor layer (A) that is unreacted is removed, and the conductive material is adhered to the produced graft polymer. Thus, a printed wiring board or a laminate with a conductive layer for formation of a printed wiring board can be provided.

(Provision of Energy)

Formation of the graft polymer of the present invention is implemented by irradiating radiation rays such as heat or light or the like. For heat, a heater or heating with infrared radiation is employed. As a light source, there are, for example, mercury lamps, metal halide lamps, xenon lamps, chemical lamps, carbon arc lamps and the like. As emitted rays, there are electron beams, X-rays, ion beams, far-infrared rays and the like. Further, g-rays, i-rays, deep-UV light, and high intensity energy beams (laser beams) are employed.

If the insulating film surface is exposed over the whole surface, the graft polymer is produced over the whole surface, and if pattern exposure is performed, the graft polymer is produced in a pattern form only at an exposed region.

The conductive material is applied to the graft polymer and a conductive film is formed. Thus, a conductive film which is excellent in adhesiveness with the smooth insulator layer can be provided.

The high adhesion between the insulating film and the conductive material is achieved by: 1. secure, high-density bonds between the insulating layer and the graft polymer; and 2. bonding by strong interaction between the produced graft polymer and the insulating material. In order to express these effects, in addition to adding the polymerization initiator into the insulating layer, it is important that compounds that interact strongly with one another are selected for the graft polymer and the conductive material.

Below, a representative method for adhering the conductive material to the graft polymer will be described.

(Method of Applying the Conductive Material to the Graft Polymer Formed at the Insulating Layer Surface)

As a step for applying the conductivity to the graft polymer, any selected from the following is preferable: (1) a step of adhering conductive fineparticles to the produced graft polymer; (2) a step of applying metal ions or metal salt to the produced graft polymer and then depositing metal reduced from the metal ions or metal ions in the metal salts; (3) a step of applying an electroless plating catalyst or precursor thereof to the produced graft polymer and implementing electroless plating; and (4) a step of applying a conductive monomer, inducing a polymerization reaction, and forming a conductive polymer layer. Further, these steps (1) to (4) may be combined, and a method of electroplating or the like may be added in order to further raise conductivity. Furthermore, after application of the conductive material, a further heating step may be included.

In the present invention, of the steps for applying the conductive material to the produced graft polymer and forming the conductive film, as (2) a step of applying metal ions or metal salt to the produced graft polymer and then depositing metal reduced from the metal ions or metal ions in the metal salts, specifically, there are: (2-1) a method of adsorbing metal ions to a graft polymer formed of a compound with polar groups (ionic groups); and (2-2) a method of impregnating a metal salt or a solution containing a metal salt into a graft polymer formed of a nitrogen-including polymer with high affinity to the metal salt, such as polyvinyl pyrrolidone, polyvinyl pyridine, polyvinyl imidazole or the like.

Further, in (3) a step of applying an electroless plating catalyst or precursor thereof to the produced graft polymer and implementing electroless plating, a method is adopted of: producing a graft polymer with a functional group that interacts with the electroless plating catalyst or precursor thereof; adding the electroless plating catalyst or precursor thereof to the graft polymer; and then implementing electroless plating and forming a metal thin film. In this mode, the graft polymer with the functional group that interacts with the electroless plating catalyst or precursor thereof bonds directly with the insulating resin. Consequently, the metal thin film that is formed shows, as well as conductivity, high strength and abrasion resistance. Moreover, with the electroless plating film that is obtained thus serving as an electrode, a conductive film of a desired thickness can be easily formed by further implementing electroplating.

For the present invention, specifically, it is preferable to implement this by any of: (1) the step of adhering conductive fineparticles to the produced graft polymer (a ‘conductive fineparticle adherence step’); (2) the step of applying metal ions or metal salt to the produced graft polymer (a ‘metal ion or metal salt application step’) and then depositing metal reduced from the metal ions or metal ions in the metal salts (a ‘metal (fineparticle) film formation step’); (3) the step of applying an electroless plating catalyst or precursor thereof to the produced graft polymer (a ‘metal electroless plating catalyst or the like application step’) and implementing electroless plating (an ‘electroless plating step’); and (4) the step of applying a conductive monomer (a ‘conductive monomer application step’), and inducing a polymerization reaction and forming the conductive polymer layer (a ‘conductive polymer layer formation step’).

(1) Step of Adhering Conductive Fineparticles

This method is a step of adhering directly conductive fineparticles to polar groups of the graft polymer, and it is sufficient if the conductive fineparticles exemplified below are adhered (adsorbed) at the polar groups electrostatically or ionically.

Conductive fineparticles provided for use in the present invention are not particularly limited as long as they have conductivity, and fineparticles formed of publicly known conductive materials can be selected and used. For example, the following are mentioned as suitable conductive fineparticles: metal fineparticles such as Au, Ag, Pt, Cu, Rh, Pd, Al, Cr and the like; oxide semiconductor fineparticles such as In₂O₃, SnO₂, ZnO, CdO, TiO₂, CdIn₂O₄, Cd₂SnO₂, Zn₂SnO₄, In₂O₃—ZnO and the like, and fineparticles using materials doped with impurities that are compatible with these; spinel-form compound fineparticles such as MgInO, CaGaO and the like; conductive nitride fineparticles such as TiN, ZrN, HfN and the like; conductive boride fineparticles such as LaB and the like; conductive polymer particles which serve as organic materials; and the like.

If the graft polymer includes anionic polar groups, the conductive film is formed here by adsorbing conductive fineparticles with positive charges. As cationic conductive fineparticles to be used here, metal (oxide) fineparticles with positive charges and the like are mentioned. With a graft polymer that includes cationic polar groups, conductive particles with negative charges are adsorbed to form the conductive film.

A diameter of the conductive fineparticles is preferably in a range from 0.1 nm to 1000 nm, and a range from 1 nm to 100 nm is more preferable. If the diameter is smaller than 0.1 nm, there will be a tendency for surfaces of the particles to continuously touch against one another and for the conductivity that is provided to fall. If they are larger than 1000 nm, there will be a tendency for contact surfaces that interact and bond with polarity-converted functional groups to be smaller, and therefore for adhesion between the hydrophilic surface and the particles to fall and strength of a conductive region to deteriorate.

(2) Step of Applying Metal Ions or Metal Salt and Then Depositing Metal Reduced from the Metal Ions or Metal Ions in the Metal Salts

In the (2) mode of the conductive material adhesion step of the present invention, a conductive pattern is formed by performing the step of applying metal ions or metal salt to the produced graft polymer (the ‘metal ion or metal salt application step’) and the step of depositing metal reduced from the metal ions or metal ions in the metal salts (the ‘metal (fineparticle) film formation step’). That is, in the (2) mode, metal ions of hydrophilic groups included in the graft polymer or the like and functional groups to which the metal salts can adhere, in accordance with functions thereof, adhere (adsorb) the metal ions or metal salt. Then, by the adsorbed metal ions or the like being reduced, metal units are deposited in a graft polymer region. By this deposition mode, a metal thin film is formed, and a metal fineparticle adhesion layer in which the metal fineparticles are dispersed is formed.

(3) Method of Applying an Electroless Plating Catalyst or Precursor Thereof and Implementing Electroless Plating

In the (3) mode of the conductive film formation step of the present invention, the graft polymer has an interacting group that interacts with the electroless plating catalyst or precursor thereof, and the conductive film is formed by the step of applying the electroless plating catalyst or precursor thereof to the graft polymer (the ‘metal electroless plating catalyst or the like application step’) and the step of performing electroless plating and forming a metal thin film (the ‘electroless plating step’), in this order. That is, in the (3) mode, the graft polymer with the functional group that interacts with the electroless plating catalyst or precursor thereof (that is, a polar group) interacts with the electroless plating catalyst or precursor thereof, and then the metal thin film is formed by the electroless plating processing that is performed.

As a result, the metal (fineparticle) film is formed. When the metal thin film (continuous film) is formed, a region of particularly high conductivity is formed. Here, after the fineparticles have been adsorbed, a heating step can be carried out with the objective of improving conductivity.

The ‘metal ion or metal salt application step’ and ‘metal (fineparticle) film formation step’ of the above-described (2) mode will be described in detail.

<Metal Ion or Metal Salt Application Step>

(Metal Ions and Metal Salts)

Metal ions and metal salts will be described.

For the present invention, a metal salt is not particularly limited as long as it dissolves in a solvent suitable for application to the graft polymer forming region and dissociates into a metal ion and a base (an anion). M(NO₃)ₙ, MClₙ, M₂/n(SO₄) and M₃/n(PO₄) (M representing an n-valency metal atom) and the like are mentioned. As metal ions, ions into which the above-mentioned metal salts dissociate can be excellently used. As specific examples, for example, Ag, Cu, Al, Ni, Co, Fe and Pd are mentioned. Ag is preferably used as a conductive film and Co as a magnetic film.

(Method of Applying Metal Ion or Metal Salt)

When the metal ions or metal salt is to be applied to the graft polymer forming region, the graft polymer includes ionic groups, and when using a method for causing the metal ions to adsorb to these ionic groups, the above-described metal salt may be dissolved in a suitable solvent, and the solvent containing the dissociating metal ions either coated onto the insulating resin layer at which the graft polymer is present or the insulating resin layer with the graft polymer immersed in the solvent. By being contacted with the solvent containing the metal ions, the ionic groups can ionically adsorb the metal ions. In regard to this adsorption being adequately implemented, a metal ion concentration or metal salt concentration in the contacted solvent is preferably in a range from 1 to 50% by weight, and is more preferably in a range from 10 to 30% by weight. As a contact duration, around 10 seconds to 24 hours is preferable, and around 1 minute to 180 minutes is more preferable.

<Metal (Fineparticle) Film Formation Step>

(Reducing Agent)

In the present invention, a reducing agent that is used for reducing the metal salt or metal ions that are present, having been adsorbed or impregnated into the graft polymer, and forming the metal (fineparticle) film is not particularly limited, as long as it reduces the metal salt compound that is used and has physical characteristics that cause the metal to be deposited. For example, hypophosphite, tetrahydroborate, hydrazine and the like are mentioned.

These reducing agents can be suitably selected in relation to the metal salt or metal ions being used. For example, if a silver nitrate aqueous solution or the like is used as a metal salt solution which provides metal ions or metal salt, sodium tetrahydroborate is mentioned, and if a palladium dichloride aqueous solution is used, hydrazine is mentioned, as a suitable reducing agent.

As a method for addition of the above-mentioned reducing agent, for example, the following are mentioned: a method of applying the metal ions or metal salt to the insulating resin layer surface at which the graft polymer is present and then removing the same to remove excess metal salt or metal ions, then immersing the insulating resin layer provided with the surface in water such as ion-exchanged water or the like, and adding the reducing agent thereto; a method of directly coating or dropping an aqueous solution of the reducing agent with a predetermined concentration onto the insulating resin layer surface; and the like. As an addition amount of the reducing agent, it is preferable to use an excessive amount of at least an amount equal to the metal ions, and an amount of at least ten times as much is more preferable.

The presence of a metal (fineparticle) film with uniformity and high strength due to the addition of the reducing agent can be verified visually by metallic gloss of the surface. However, the structure thereof can be verified by inspecting the surface using a transmission electron microscope or an AFM (atomic force microscope). Further, for a film thickness of the metal (fineparticle) film, this can easily be implemented by a usual method, for example, a method of inspecting a cut surface with an electron microscope or the like.

(Relationship Between Polarity of Functional Group Included in Graft Polymer and Metal Ions or Metal Salt)

If the graft polymer has a functional group with a negative charge, here, metal ions with positive charge are adsorbed, and a region at which the metal units (metal thin film and metal fineparticles) are deposited is formed by these adsorbed metal ions being reduced. If the graft polymer has, as a hydrophilic functional group as described in detail earlier, an anionic group such as a carboxyl group, a sulfone acid group, a phosphone acid group or the like, this selectively has negative charge. Here, metal ions with positive charges are adsorbed, and a metal (fineparticle) film region (for example, wiring or the like) is formed by these adsorbed metal ions being reduced.

On the other hand, if the graft polymer chain has a cationic group, such as an ammonium group or the like as described in JP-A No. 10-296895, this selectively has positive charge. Here, a solution containing the metal salt or a solution in which the metal salt is dissolved is impregnated, the metal ions or metal ions in the metal salt in the impregnated solution are reduced, and thus a metal (fineparticle) formation region (wiring) is formed.

These metal ions are preferable to bond with the hydrophilic groups of the hydrophilic surface at a maximum quantity applicable (adsorbable) in regard to endurance.

As a method for applying the metal ions to the hydrophilic groups, a method of coating a liquid in which the metal ions or metal salt are dissolved or dispersed onto the support surface, a method of immersing the support surface in such a solution or dispersion, and the like are mentioned. In either case, coating or immersion, in order to provide an excessive quantity of metal ions and realize conduction by plentiful ionic bonds with the hydrophilic groups, a duration of contact between the solution or dispersion and the support surface is preferably around 10 seconds to 24 hours, and is more preferably around 1 minute to 180 minutes.

As well as just one type, the metal ions can be used in a combination of a plurality of types as necessary. Further, in order to obtain a desired conductivity, a plurality of materials may be mixed beforehand and used.

For the conductive film that is formed in the present invention, it is verified that the metal fineparticles are fully dispersed in the surface graft film by surface inspection and cross-section inspection with an SEM or AFM. A size of the fineparticles that are manufactured is a particle diameter of around 1 μm to 1 nm.

The conductive film that is manufactured by the procedure described above may be used as is if the metal fineparticles are densely adsorbed and the metal film is visibly formed. However, with regard to efficiently assuring conductivity, it is preferable to perform further heating processing of the pattern that is formed.

As a heating temperature of a heating processing step, 100° C. or above is preferable, 150° C. or above is more preferable, and around 200° C. is particularly preferable. In consideration of processing efficiency, dimensional stability of the support insulating resin layer and the like, the heating temperature is preferably 400° C. or less. Further, with regard to the heating duration, it is preferably 10 minutes or more, and more preferably around 30 minutes to 60 minutes. A mechanism of operation caused by the heating processing is not clear, but it is thought that conductivity can be improved by a portion of the metal fineparticles that are close together fusing to one another.

Next, the ‘electroless plating catalyst or the like application step’ and ‘electroless plating step’ of the (3) mode of the conductive material application step of the present invention will be described.

<Electroless Plating Catalyst or the Like Application Step>

In this step, an electroless plating catalyst or precursor thereof is applied to the graft polymer that has been produced by the surface graft step described earlier.

(Electroless Plating Catalyst)

The electroless plating catalyst that is used in this step is generally a zero-valency metal, and Pd, Ag, Cu, Ni, Al, Fe and Co and the like are mentioned. For the present invention, in particular, Pd and Ag are preferable due to good handling characteristics and high catalytic ability. As a procedure for fixing a zero-valency metal to an interacting region, for example, a procedure of deploying a metal colloid, with charge adjusted so as to interact with the interacting groups in the interacting region, at the interacting region is used. Ordinarily, a metal colloid can be manufactured by reducing metal ions in a solution in which a surfactant having charge or a protective agent having charge is present. The charge of the metal colloid can be adjusted by the surfactant or protective agent that is employed here, and the metal colloid with charge adjusted in this manner is caused to interact with the interacting groups included in the graft polymer (polar groups). Thus, the metal colloid (electroless plating catalyst) can be adhered to the graft polymer.

(Electroless Plating Catalyst Precursor)

An electrolytic plating catalyst precursor that is used for this step is not particularly limited and can be employed as long as it is capable of forming an electroless plating catalyst by a chemical reaction. Generally, metal ions of the zero-valency metals that are used for the above-described electroless plating catalysts are used. Metal ions that are an electroless plating catalyst precursor produce a zero-valency metal which will be an electroless plating catalyst, by a reduction reaction. The metal ions that are the electroless plating catalyst precursor may be applied to the substrate in the earlier-described step (b) and then, before immersion in an electroless plating bath, converted to the zero-valency metal by a separate reduction reaction to form the electroless plating catalyst, or the electroless plating catalyst precursor may be immersed in an electroless plating bath as is, and converted to the metal (electroless plating catalyst) by a reducing agent in the electroless plating bath.

In practice, metal ions that are an electroless plating precursor are applied to the graft polymer in a metal salt state. A metal salt to be employed is not particularly limited as long as it dissolves in a suitable solvent and dissociates into metal ions and base (anions), and M(NO₃)ₙ, MClₙ, M₂/n(SO₄) and M₃/n(PO₄) (M representing an n-valency metal atom) and the like are mentioned. As metal ions, ions into which the above-mentioned metal salts dissociate can be excellently used. As specific examples, for example, Ag ions, Cu ions, Al ions, Ni ions, Co ions, Fe ions and Pd ions are mentioned, and Ag ions and Pd ions are preferable with regard to catalytic capability.

As a method for applying the metal colloid which is an electroless plating catalyst or the metal salt which is an electroless plating precursor to the graft polymer, the metal colloid may be dispersed in a suitable dispersion medium or the metal salt dissolved in a suitable solvent, to prepare a solution containing dissociated metal ions, and this solution may be coated onto the insulating resin layer surface at which the graft polymer is present, or the laminate including the insulating resin layer with the graft polymer may be immersed in the solution. By contact with the solution containing the metal ions, the metal ions can be adhered to the interacting groups that the graft polymer includes, using ion-ion interaction or bipole-ion interaction, or the metal ions can be impregnated into the interactive region. With a view to performing such adherence or immersion thoroughly, a metal ion concentration or metal salt concentration in the solution that is contacted is preferably in a range from 0.01 to 50% by weight, and is more preferably in a range from 0.1 to 30% by weight. Furthermore, as a contact duration, around 1 minute to 24 hours is preferable, and around 5 minutes to 1 hour is more preferable.

<Electroless Plating Step>

In this step, the electroless plating is performed on the insulating resin layer to which the electroless plating catalyst or the like has been applied by the electroless plating catalyst or the like application step, and thus the conductive film (metal film) is formed. That is, by the performance of electroless plating in this step, a conductive film (metal film) with high density is formed at the graft polymer provided by the earlier-described steps. The conductive film (metal film) that is formed has excellent conductivity and adhesiveness.

(Electroless Plating)

Electroless plating means an operation for depositing a metal by a chemical reaction, using a solution in which metal ions that are to be deposited as the plating are dissolved.

The electroless plating in the present step is performed by, for example, rinsing a substrate to which an electroless plating catalyst has been provided by the electroless plating precursor catalyst or the like application step, removing excess electroless plating catalyst (metal), and then immersing the substrate in an electroless plating bath. As the electroless plating bath to be employed, an electroless plating bath that is commonly known can be employed.

In a case in which a substrate to which an electroless plating catalyst precursor has been applied is to be immersed in the electroless plating bath in a state in which the electroless plating catalyst precursor has adhered or impregnated into the graft polymer, the substrate is rinsed and excess precursor (metal salt or the like) is removed, and then it is immersed in the electroless plating bath. In this case, in the electroless plating bath, reduction of the precursor and subsequent electroless plating are implemented. As the electroless plating bath that is employed here, similarly to the above, an electroless plating bath that is commonly known can be employed.

A composition of a common electroless plating bath principally includes 1. metal ions for plating, 2. a reducing agent and 3. an additive that improves stability of the metal ions (a stabilizer). In addition to these, publically known additives such as a plating bath stabilizer and the like can be included in the plating bath.

As a type of metal to be used for the electroless plating bath, copper, tin, lead, nickel, gold, palladium, and rhodium are known. Of these, copper and gold are particularly preferable with regard to conductivity.

Further, there are optimum reducing agents and additives for the above-described metals. For example, a copper electroless plating bath includes Cu(SO₄)₂ as a copper salt, HCOH as a reducing agent, and a chelate such as EDTA or Rochelle salt or the like, which is a stabilizer of copper ions, as an additive. Further, a plating bath which is employed for electroless plating of CoNiP includes cobalt sulfate or nickel sulfate as a metal salt thereof, sodium hypophosphate as a reducing agent, and sodium malonate, sodium malate or sodium succinate as a complexing agent. Further yet, a palladium electroless plating bath includes (Pd(NH₃)₄)Cl₂ as metal ions, NH₃ or H₂NNH₂ as a reducing agent and EDTA as a stabilizer. Components other than the components described above may be included in these plating baths.

A film thickness of the conductive film (metal film) that is formed in this manner can be controlled by a metal salt or metal ion concentration in the plating bath, an immersion duration in the plating bath, a temperature of the plating bath and the like, and with regard to conductivity is preferably at least 0.1 μm and more preferably 3 μm or less. Further, the immersion duration in the plating bath is preferably around 1 minute to 3 hours, and more preferably around 1 minute to 1 hour.

For a conductive film (metal film) provided as described above, it has been confirmed by cross-section inspection with an SEM that the electroless plating catalyst and plating metal fineparticles are thoroughly dispersed in the surface graft layer, and further that particles which are comparatively larger are deposited thereabove. Because the surface is in a hybrid state of the graft polymer and the fineparticles, even when an unevenness difference at the interface of the substrate (an organic component) and an inorganic material (the electroless plating catalyst or plating metal) is 100 nm or less, adhesiveness is excellent.

<Electroplating Step>

In the (3) mode of the conductive pattern formation method of the present invention, after the above-described electroless plating step is performed, a step of performing electroplating (an electroplating step) may be included.

In this step, after the electroless plating of the electroless plating step, the metal film (conductive film) formed by that step serves as an electrode, and further electroplating can be performed. Thus, with the metal film which is excellent in adhesiveness with the insulating resin layer serving as a base, a metal film having an arbitrary thickness can easily be newly formed thereon. By the addition of this step, the metal film can be formed to a thickness in accordance with objectives, and the conductive material provided by this mode is excellent for employment in various applications.

As a method of electroplating in the present mode, previous publicly known methods can be used. Here, as a metal to be used for electroplating in this step, copper, chromium, lead, nickel, gold, silver, tin, zinc and the like are mentioned. With regard to conductivity, copper, gold and silver are preferable, and copper is more preferable.

A film thickness of the metal film that is provided by the electroplating will differ depending on application, and can be controlled by adjustment of a metal concentration included in the plating bath, immersion duration, current density or the like. Here, with regard to conductivity, the film thickness in a case of use for ordinary electronic wiring or the like is preferably 0.3 μm or more and more preferably 3 μm or more.

Further, besides the electroplating step in the present invention being performed in order to form a pattern-form metal film to a thickness in accordance with objectives, the electroplating can be performed for objectives such as, for example, enabling application to mounting of an integrated circuit or the like, and the like. For a conductive film or metal pattern surface that is formed of copper or the like, plating that is performed with this objective can be performed using a material selected from the group consisting of nickel, palladium, gold, silver, tin, solder, rhodium, platinum, and compounds thereof.

Next, the ‘conductive monomer application step’ and ‘conductive polymer layer formation step’ of the (4) mode of the conductive material application step relating to the present invention will be described.

The (4) mode of the conductive material application step is a method of ionically adsorbing a conductive monomer described herebelow at an interacting group included in the aforementioned graft polymer, particularly preferably an ionic group, and then inducing a polymerization reaction as is and forming a conductive polymer layer. By this method, a conductive layer formed of a conductive polymer can be formed.

Here, the conductive layer formed of the conductive polymer has advantages in that, because the interacting group of the graft polymer and the ionically adsorbed conductive monomer are polymerized, it is excellent in adhesiveness with the substrate and endurance, and in that it is possible to implement control of film thickness and conductivity by adjusting polymerization reaction conditions such as a rate of provision of the monomer and the like.

A method for forming such a conductive polymer layer is not particularly limited, but with regard to being able to form an ordinary thin film, it is preferable to use the method described herebelow.

First, the substrate at which the graft polymer has been produced is immersed in a solution containing a polymerization catalyst, such as potassium persulfate, iron (III) sulfate or the like, and a compound with a polymerization initiation capability. While this liquid is agitated, a monomer capable of forming the conductive polymer is progressively dropped in, for example, 3,4 ethylene dioxythiophene or the like. Accordingly, the interacting group (ionic group) in the graft polymer, to which the polymerization catalyst and polymerization initiation capability have been applied, and the monomer capable of forming the conductive polymer are securely adsorbed by interacting. In addition, a polymerization reaction between the monomer progresses, and a very thin film of a conductive polymer is formed on the graft polymer of the insulating resin layer obverse side surface. Thus, a uniform, thin conductive polymer layer is provided.

As a conductive polymer that can be employed in this method, any polymer can be employed as long as it is a polymer compound with a conductivity of 10⁻⁶ s·cm⁻¹ or more, and preferably 10⁻¹ s·cm⁻¹ or more. Specifically however, for example, the following can be mentioned: a substituted or unsubstituted conductive polyaniline, polyparaphenylene, polyparaphenylene vinylene, polythiophene, polyfuran, polypyrrole, polyselenophene, polyisothianaphthene, polyphenylene sulfide, polyacetylene, polypyridyl vinylene, polyazine and the like. One type of these may be used alone, and two or more types may be used in combination depending on objectives. Furthermore, within a range in which a desired conductivity can be achieved, these can be used as a mixture with another polymer which does not have conductivity, and a copolymer of a monomer of these with another monomer which does not have conductivity can be used.

In the present invention, the conductive monomer itself is securely adsorbed by forming an interaction electrostatically or by polarity with the interactive group of the graft polymer. Therefore, the conductive polymer layer which is formed by polymerization of these forms a secure interaction with the graft polymer. Therefore, even when it is a thin film, it has sufficient strength with respect to scraping and scratching.

Further, by selecting materials such that the conductive polymer and the interacting group of the graft polymer adsorb with a cation and anion relationship, the interacting group is adsorbed as a counter-anion of the conductive polymer, and functions as a type of dopant. Therefore, an effect can be provided in that it is possible to further improve conductivity of the conductive polymer layer (a conductivity-expressing layer). Specifically, for example, by selecting styrene sulfonate as the polymerizable compound with the interacting group and thiophene as the material of the conductive polymer, respectively, and interacting the two, polythiophene is present with a sulfonate group (sulfo group) serving as the counter-anion at the interface of the graft polymer and the conductive polymer layer, and this functions as a dopant of the conductive polymer.

A film thickness of the conductive polymer layer that is formed at the surface of the graft polymer is not particularly limited, but a range from 0.01 μm to 10 μm is preferable, and a range from 0.1 μm to 5 μm is more preferable. Provided the film thickness of the conductive polymer layer is within such a range, sufficient conductivity and transparency can be achieved. If it is 0.01 μm or less, there will be concern that conductivity is insufficient, so this is unpreferable.

In the present invention, when the conductive layer is formed over the whole surface of the insulating resin surface by the above-described method, a conductive pattern material can be formed by etching this conductive layer.

(Step of Etching Metal Film and Forming Metal Pattern)

As an etching process in a method of etching the metal film at the conductive material surface provided by the present invention to form a metal pattern, subtractive processes and semi-additive processes are used.

(Subtractive Process)

A subtractive process refers to a method of, on the metal film manufactured by the above-described procedure, (1) formation of a resist layer by coating or lamination→(2) pattern exposure and resist pattern formation of conductors that are to be left by development→(3) removal of unneeded metal film by etching→(4) stripping of the resist layer and formation of the metal pattern. A film thickness of the metal film that is employed in this mode is preferably at least 5 μm, and is more preferably in a range from 5 to 30 μm.

—(1) Resist Layer Coating Step—

—The Resist—

As a photosensitive resist that is employed, a photo-curing negative resist or a positive resist of a photo-soluble type which is dissolved by exposure can be employed. As a photosensitive resist, 1. a photosensitive dry film resist (DFR), 2. a liquid resist, and 3. an ED (electrodeposition) resist can be employed. These have respective features. 1. A photosensitive dry film resist (DFR) can be used in a dry state, so handling is easy. 2. A liquid resist can be formed into a thin film as a resist, so a pattern can be created with good resolution. 3. An ED (electrodeposition) resist can be formed as a resist with a thin film thickness, so a pattern can be created with good resolution, and characteristics of following unevenness of a coating surface are good, so adhesiveness is excellent. The resist that is employed may be suitably selected in consideration of these characteristics.

—Coating Method—

1. Photosensitive Dry Film

A photosensitive dry film ordinarily has a sandwich structure which is sandwiched by a polyester film and a polyethylene film, and is pressed by a heating roller while the polyethylene film is being peeled off by a laminator.

For a photosensitive dry film resist, this treatment, a film fabrication method and a lamination method are described in detail in paragraphs [0192] to [0372] of the specification of Japanese Patent Application No. 2005-103677, which was previously submitted by the present inventor, and these descriptions can also be applied to the present invention.

2. Liquid Resist

For a coating method, there are spray coating, roll coating, curtain coating and dip coating. For coating both sides simultaneously, of these, roll coating and dip coating are capable of coating both sides simultaneously, and are preferable.

Liquid resists are described in detail in paragraphs [0199] to [0219] of the specification of Patent Application No. 2005-188722, previously submitted by the present inventor, and these descriptions can also be applied to the present invention.

3. ED (Electrodeposition) Resist

An ED resist is formed as a colloid in which a photosensitive resist is formed into microscopic particles and suspended in water. The particles carry charge, so when a voltage is applied to a conductive layer, the resist is deposited on the conductive layer by electrophoresis, the colloid on the conductor bonds together and forms a film, and coating is possible.

—(2) Pattern Exposure Step—

—Exposure—

A mask film or dry plate is adhered to a substrate on which a resist film is provided over the metal film, and exposed with light in a photosensitivity range of the resist that is employed. When a film is used, it is adhered with a vacuum printing frame and exposed. Concerning an exposure light source, a point light source with a pattern width of around 100 μm can be used. If a pattern width of 100 μm or less is to be formed, it is preferable to use a parallel light source.

—Development—

As long as, with a light-curable negative resist, an unexposed portion is dissolved or, with a photo-soluble positive resist that is dissolved by light exposure, an exposed portion is dissolved, anything may be employed. However, generally, organic solvents and alkaline aqueous solutions are employed. In recent years, alkaline aqueous solutions have been employed because of reductions in environmental burdens.

—(3) Etching Step—

—Etching—

Etching chemically dissolves the metal layer that is exposed where there is no resist, and is a step for forming a conductive pattern. An etching step is generally implemented by spraying an etching fluid from above and below at a horizontal conveyor device. The etching fluid is an oxidizing aqueous solution which oxidizes and dissolves the metal layer. Fluids which are used as an etching fluid are a ferric chloride fluid, a cupric chloride fluid and an alkaline etchant. Because the resist might be stripped away and removed by an alkali, generally a ferric chloride fluid or a cupric chloride fluid is employed.

In the method of the present invention, removability of conductive components near the substrate interface is good because the substrate interface is not made uneven. In addition, because the graft polymer introducing the metal film onto the substrate bonds with the substrate at terminals of the polymer chains and has a structure which is very high in mobility, the etching fluid can be easily dispersed in the graft polymer layer in this etching step, and removability of the metal components at the interface portion between the substrate and the metal layer is excellent. Therefore, pattern formation with excellent sharpness is possible.

—(4) Resist Stripping Step—

—Stripping Step—

After etching and completion of a metal (conductive) pattern, unneeded etching resist is not required, so a step of stripping is necessary. The stripping can be performed by spraying a stripping fluid. The stripping fluid differs depending on the type of resist, but commonly a solvent or a solution that causes the resist to swell is wiped on by spraying to swell and strip the resist.

(Semi-Additive Process)

A semi-additive process is a metal pattern formation method of, on the metal film formed on the graft polymer, (1) coating of a resist layer→(2) pattern exposure and formation of a resist pattern of conductors that are to be removed by development→(3) formation of a metal film at non-pattern portions of the resist by plating→(4) stripping of a DFR→(5) removal of unneeded metal film by etching and formation of the metal pattern. The similar procedures as described in “Subtractive Process” can be employed in these steps. As a plating procedure, the electroless plating and electrode plating described above can be employed. As a film thickness of the metal film that is employed, in order to finish the etching step in a short time, 1 to 3 μm is preferable. Electroless plating and electrode plating may be further performed on the metal pattern that is formed.

Thus, a conductive pattern material using the conductive material provided in the present invention can be obtained by an etching method. Because the conductive material provided by the present invention forms a metal film with high adhesiveness on a smooth substrate, a fine metal pattern with high adhesiveness to the smooth substrate is formed, and therefore this is useful in formation of various electrical circuits.

As described above, by using the laminate of the present invention, a printed wiring board with excellent characteristics can be easily formed at an arbitrary solid surface. That is, a metal film material which expresses high adhesive strength can be provided using, for example, a coppered laminate board or the like, without roughening a surface of an insulating resin material layer with heat resistance and low dielectric effectiveness, such as an epoxy resin, polyimide resin, liquid crystal resin or polyarylene resin, which are employed as substrates in the field of printed wiring boards.

With a conductive material such as a coppered laminate board or the like that is provided by the method of manufacturing of the present invention, it is possible, for example, by publicly known etching processing or the like, to form copper wiring with a fineness of 20 μm or below and high adhesiveness, which has been difficult with previous technologies.

(Method for Manufacturing Multi-layer Printed Wiring Board)

Next, a method for manufacture of a multi-layer printed wiring board using the laminate for a printed wiring board of the present invention will be described with reference to the drawings.

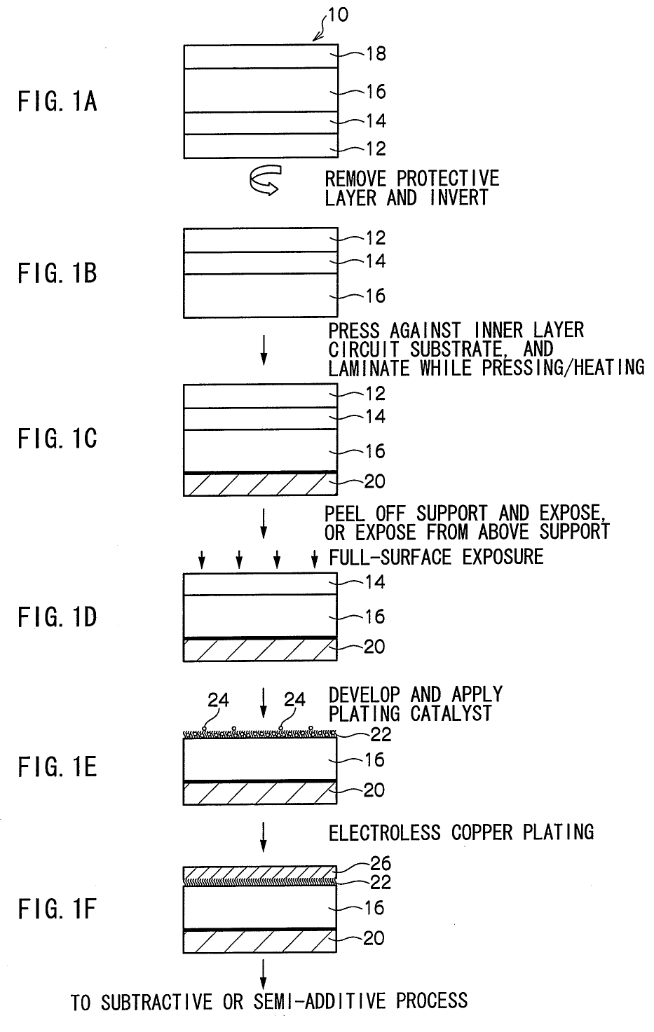

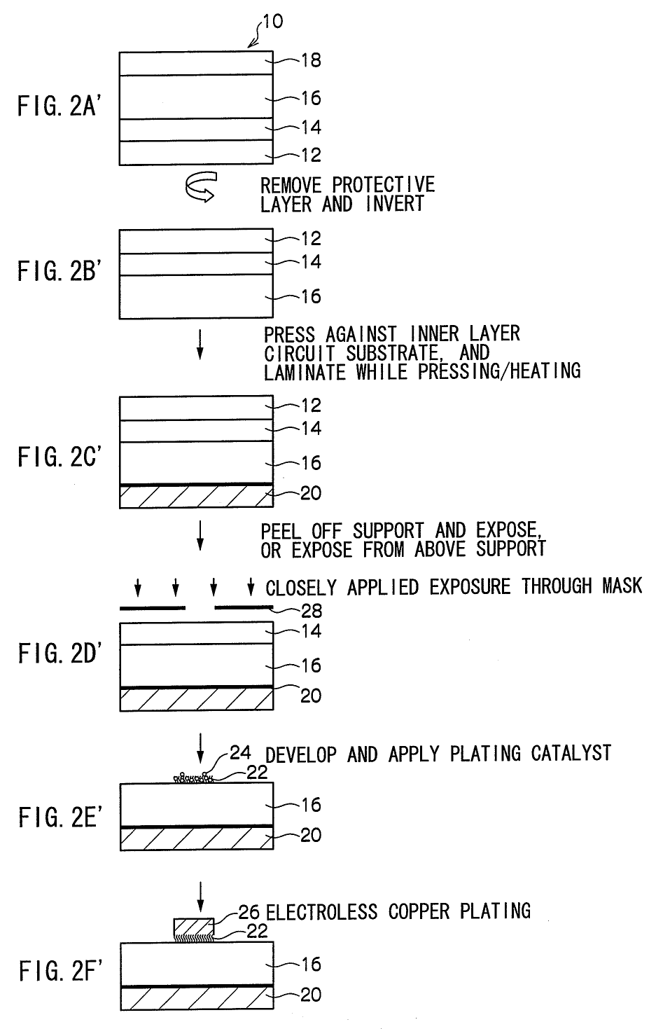

Steps FIG. 1A to FIG. 1F are schematic sectional diagrams showing steps of forming a conductive layer over the whole surface of a desired integrated circuit mounting surface, using the laminate for a printed wiring board of the present invention. Steps FIG. 2A′ to FIG. 2F′ are schematic sectional diagrams showing steps of forming a conductive layer in a pattern at a portion of a desired integrated circuit substrate surface, using the laminate for a printed wiring board of the present invention.

Step FIG. 1A shows a laminate 10 of the present invention. This laminate 10 is formed by laminating a polymer precursor layer 14 and an insulating resin composition layer 16 in this order at a surface of a support 12, and includes a protective layer 18 at the surface thereof. When the laminate 10 is being applied to an inner layer circuit substrate 20 that has been subjected to pattern processing, as shown in step FIG. 1B, the protective film is removed, and then the laminate 10 is inverted and the insulating resin composition layer 16 is disposed at the side of the inner layer circuit substrate 20. As shown in step FIG. 1C, the two are stuck together, and the insulating resin composition layer (insulating film) 16 attached to the polymer pricursor layer 12, which is solid at room temperature, is pressed from the side of the support (base film) 12, and laminated while being heated. Here, although not illustrated, by laminating in conditions in which a resin flow during lamination is at least a conductor thickness of the inner layer circuit, and this is at least half of a through-hole depth of the inner layer circuit and/or at least a surface via hole depth, covering of the inner layer circuit pattern and resin filling in through-holes and/or surface via holes can be implemented all together at the same time.

Here, as the inner layer circuit substrate 20, it may have a substrate of a glass epoxy or metal, polyester, polyimide, a thermosetting-type polyphenylene ether, polyamide, polyaramide, paper, glass cloth, glass non-woven cloth, liquid crystal polymer or the like, and can employ a substrate using, as a resin, a phenol resin, an epoxy resin, an imide resin, a BT resin, a PPE resin, a tetrafluoroethylene resin or the like as a resin. The circuit surface may be or may not be subjected to roughening processing beforehand.

The lamination is under reduced pressure, may be a batch system or may be a continuous system with a roll, and one face may be laminated or both faces may be laminated simultaneously. However, laminating two faces simultaneously is preferable. Lamination conditions as described above differ in accordance with a melt viscosity during heating of the composition structuring the insulating resin composition layer 16 which is solid at room temperature of the present invention, a thickness, and a through-hole diameter and depth and/or a surface via hole diameter and depth of the inner layer circuit substrate 20, but it will ordinarily be preferable to laminate with a pressing temperature of 70 to 200° C. and a pressing pressure of 1 to 10 kgf/cm², under a reduced pressure of 20 mmHg or less. If through-hole diameters are larger and deeper, that is, the substrate thickness is thicker, the resin composition will be thicker and laminating conditions with high temperature and/or high pressure will be necessary.

Ordinarily, excellent resin filling is possible when a board thickness is up to around 1.4 mm or less and a through-hole diameter is up to around 1 mm or less. A surface smoothness of the insulating resin composition layer 16 after lamination is more excellent when the support base film 12 is thicker, but this is disadvantageous for embedding resin between circuit patterns without voids. Thus, it is preferable if the support base film 12 has the conductor thickness ±20 μm. However, because the conductor thickness of the inner layer circuit 20 is thick, a surface smoothness or thickness of resin on the pattern is not sufficient, and because diameters of through-holes and surface via holes are large and deep, hollows occur in the holes. In this case, if a further laminate for a printed wiring board of the present invention is laminated thereon, it is possible to match with various conductor thicknesses and board thicknesses. After lamination, the support base film 12 is stripped off, after cooling to near room temperature.

After laminating the laminate 10 for a printed wiring board on the inner layer circuit substrate 20, if a further wiring pattern is to be formed on the resin composition that has been thermosetted according to necessity, conditions of heating and setting differ with the type of material of the inner layer circuit substrate, the type of resin composition structuring the laminate for a printed wiring board 10, and the like. Depending on the setting temperatures of these formation materials, selections can be made in ranges from 120 to 220° C. and 20 minutes to 120 minutes.

Formation of the wiring pattern is performed as follows. After the lamination, the resin composition in the insulating resin composition layer 16 is thermosetted as necessary. The conditions of the thermosetting are selected in ranges of 120 to 220° C. and 20 minutes to 120 minutes. The support 12 may be peeled off straight after lamination, and may be peeled off after thermosetting or after active light ray irradiation. If the wiring pattern (conductive layer) is to be formed using an earlier-mentioned subtractive process or semi-additive process, in order to form the whole conductive layer, as shown in step FIG. 1D, active light rays (for example, an electron beam, UV light or the like) are irradiated at the whole, and a graft polymer 22 that directly bonds with the insulating layer surface is produced. A method of light irradiation may be direct irradiation with something such as a laser, or a plate with small absorption and reflection with respect to the irradiated light may be pre-applied to the polymer precursor layer and the light irradiated therethrough.

Thereafter, unreacted polymerizable compound which has not contributed to graft polymer formation is removed by development or washing processing. This production of the graft polymer 22 by light irradiation and removal of the unreacted may be implemented after carrying out the following hole-forming step.

In a case of forming the wiring pattern (conductive layer) using the earlier-mentioned subtractive process or semi-additive process, an electroless plating catalyst or precursor thereof 24 is adhered by a method described earlier, as shown in step FIG. 1E, and a conductive layer 26 is formed by electroless plating, as shown in step FIG. 1F. On this graft polymer layer 22, using the conductive layer 26 which is formed over the whole surface of the circuit surface, thereafter, the wiring pattern (a conductive layer in a pattern: a circuit) is formed using the earlier-described subtractive process or semi-additive process.

When a pattern is to be formed using a pattern formation capability of the graft polymer, steps FIG. 2A′ to FIG. 2F′ are performed. The laminate 10 is prepared, and the steps shown in steps FIG. 2A′ to FIG. 2C′, which are steps for laminating this onto an inner circuit substrate, are performed in exactly the same manner as the above-described steps FIG. 1A to FIG. 1C. Then, as shown in step FIG. 2D′, a mask pattern 28 is closely applied to the surface of the polymer precursor layer 14 and light exposure is performed. By performing such pattern light exposure, as shown in step FIG. 2E′, the graft polymer 22 is produced in a pattern form only at an exposed region. The pattern exposure can be performed by a method of performing whole surface exposure through the mask pattern 28 in this manner, or by a method of scanning exposure with laser light or the like in the pattern form only at desired regions.

Thereafter, unreacted polymerizable compound which has not contributed to graft polymer formation is removed by development or washing processing. This production of the graft polymer 22 by light irradiation and removal of the unreacted may be implemented after carrying out the following hole-forming step.

Next, the electroless plating catalyst or precursor thereof 24 is adhered to the pattern-form graft polymer 22 by the method described earlier, and the conductive layer 26 is formed by electroless plating. At this time, the conductive layer 26 is formed only at the pattern-form production region of the graft polymer 22 as shown in step FIG. 2F′, and the pattern-form conductive layer 26 is formed.

After the whole-surface or pattern-form conductive layer 26 has been formed by these steps, hole-formation is performed with a laser and/or a drill at predetermined through-hole and/or via hole portions.

The surface of the polymer precursor layer is roughened by a dry system and/or wet system process as necessary. As a dry system roughening process, mechanical grinding, such as buffing, sandblasting or the like, and plasma etching and the like are mentioned. On the other hand, as a wet system roughening process, chemical product treatments such as methods using oxidizing agents, such as chlorine permanganate, chlorine bichromate, ozone, hydrogen peroxide/sulfuric acid, nitric acid and the like, strong bases, resin swelling solvents and the like, and the like can be mentioned. In the present invention, roughening is not necessarily required, and it is sufficient to remove smears that are caused when forming holes with a laser and/or drill at through-hole and/or via hole portions as much as possible.

Then, the electroless plating catalyst or precursor thereof is applied to the graft polymer forming region, by the method described earlier, and the conductive layer is formed by electroless plating.

A more detailed method of forming by electroless plating is as follows.

In order to apply the plating catalyst to the graft polymer fixed onto the insulating film, it is immersed in a plating catalyst liquid (for example, a silver nitrate solution or a tin-palladium colloid solution). As the electroless plating catalyst, metallic fine powders such as palladium, gold, platinum, silver, copper, nickel, cobalt, tin and the like and/or halides, oxides, hydrates, sulfides, peroxides, amine salts, sulfide salts, nitrate salts, organic salts, organic chelate compounds and the like thereof are mentioned. These may be adsorbed with various inorganic components. As inorganic components in such a case, any are possible of they are fine powders of previously known components, such as colloidal silica, calcium carbonate, magnesium carbonate, magnesium oxide, barium sulfate, barium titanate, silicon oxide, amorphous silica, talc, clay, mica and the like, and also alumina and carbon. At such a time, as a size of the fine powder, an average particle diameter of 0.1 to 50 μm is preferable.

Then, partially remaining plating catalyst solution that will not form the wiring pattern is removed by rinsing. The plating catalyst cannot fix to a graft polymer non-production region, and the plating catalyst solution is removed. Then, by carrying out the electroless plating with this, electroless plating is implemented only at portions at which the wiring pattern conductive layer is formed, the conductive layer is formed, and a multi-layer printed wiring circuit can be constructed.

After the conductive layer is formed in this manner, by performing annealing processing for 20 minutes to 120 minutes at 120 to 220° C. as necessary, curing of the thermosetting resin is advanced, and peeling strength of the conductive layer can be further improved.

When the laminate for a printed wiring board of the present invention is employed, a printed wiring board that is provided is excellent in surface smoothness. Thus, a manufacturing process as described above can be multiply repeated and a multi-layer printed wiring board in which build-up layers are layered in a number of levels can be manufactured.

The whole of the disclosure of Japanese application, Patent Application No. 2005-322867 is incorporated into the present specification by reference.

### INDUSTRIAL APPLICABILITY

The laminate for a printed wiring board of the present invention is useful for formation of a printed wiring board and flexible wiring board which realize high adhesive strength without surface-roughening of an insulating film surface, when using a heat resistive, low dielectric constant resin, such as an epoxy resin, polyimide resin, liquid crystal resin, polyarylene resin or the like, as the insulating film material.

Herebelow, examples will be offered and the present invention concretely described. However, the present invention is not to be limited to these.

### EXAMPLES 1 to 5

Herebelow, common details of Examples 1 to 5 will be described.

(Manufacture of Laminate in which Graft Polymer Precursor Layer is Coated onto Insulating Film)

A graft polymer precursor layer was provided at the surface of a polyethylene terephthalate film with thickness 16 μm, serving as a support, by coating a liquid composition 1 of the following composition with a rod bar #6 and drying for 1 minute at 100° C., without performing respective surface treatments or prior treatments. The liquid composition 1 included a polymer with acrylic groups serving as a polymerizable compound and carboxyl groups serving as an interactive group (a hydrophilic polymer with polymerizable groups in side chains: P-1, obtained by the synthesis example described below). The film thickness of the polymer precursor layer was prepared so as to be in a range from 0.2 to 1.5 μm.

(Liquid Composition 1 Containing Polymerizable Compound)

Hydrophilic polymer with polymerizable groups in side chains (P-1) 3.1 g

Water 24.6 g

1-methoxy-2-propanol 12.3 g

(Synthesis Example: Synthesis of Polymer with Double Bonds P-1)

60 g of polyacrylic acid (average molecular weight 25,000, Wako Pure Chemical Industries, Ltd.) and 1.38 g (0.0125 mol) of hydroquinone (Wako Pure Chemical Industries, Ltd.) were put into a triple-neck flask (1 L) provided with a cooling tube, 700 g of N,N-dimethyl acetamide (DMAc, Wako Pure Chemical Industries, Ltd.) was added, stirred at room temperature, and uniformly dissolved. While stirring this solution, 64.6 g (0.416 mol) of 2-methacryloyloxyethyl isocyanate (KARENZ MOI, Showa Denko K.K.) was dropped in. Then, 0.79 g of di-n-butyltin dilaurate (Tokyo Chemical Industry Co., Ltd.) suspended in 30 g of DMAc (1.25 g×10⁻³ mol) was dropped in. While stirring, this was heated in a water bath at 65° C. After 5 hours, heating was stopped, and it naturally cooled to room temperature. Acid value of this reaction fluid gave 7.105 mmol/g, with solid content of 11.83%.

300 g of the reaction fluid was taken in a beaker, and cooled to 5° C. in an ice bath. While stirring this reaction fluid, 41.2 mL of a 4N sodium hydroxide aqueous solution was dropped in over about 1 hour. The temperature of the reaction fluid during the dropping was 5° C. to 1° C. After the dropping, the reaction fluid was stirred at room temperature for 10 minutes, the solid content was removed by suction filtration, and a brown solution was obtained. This solution was re-precipitated in 3 L of ethyl acetate, and deposited solids were filtered out. These solids were re-slurried overnight in 3 L of acetone. Solids were separated by filtration, vacuum-dried for 10 hours, and a light brown powder P-1 was obtained. When 1 g of this polymer was dissolved in a mixed solvent of 2 g of water and 1 g of acetonitrile, pH was 5.56 and viscosity was 5.74 cps. (The viscosity was measured at 28° C. with an RE80 viscometer, Toki Sangyo Co., Ltd., using a rotor 30XR14.) A molecular weight according to GPC was 30,000.

Herebelow, each of Examples 1 to 5 will be described.

### EXAMPLE 1

### Example 1

### Formation of Epoxy Insulator Layer Containing Initiator

20 parts by weight (below, mixture quantities are all represented by parts by weight) of bisphenol A-type epoxy resin (epoxy equivalent 185, EPICOAT 828, made by Yuka Shell Epoxy KK), 45 parts of cresol novolac-type epoxy resin (epoxy equivalent 215, EPICLON N-673, made by Dainippon Ink and Chemicals, Incorporated) and 30 parts of phenol novolac resin (phenolic hydroxyl group equivalent 105, PHENOLITE, made by Dainippon Ink and Chemicals, Incorporated) were heated and dissolved while being stirred in 20 parts of ethyl diglycol acetate and 20 parts of solvent naphtha, and cooled to room temperature. Then, 30 parts of a cyclohexanone varnish (YL6747H30, made by Yuka Shell Epoxy KK, non-volatile portion 30% by weight, weight-average molecular weight 47,000) of a phenoxy resin formed of the EPICOAT 828 and bisphenol S, 0.8 parts of 2-phenyl-4,5-bis(hydroxymethyl)imidazole, and also 2 parts of pulverized silica and 0.5 parts of a silicon-based antifoaming agent were added thereto, and an epoxy resin varnish was manufactured.

Further, 10 parts of a polymerization initiation polymer P synthesized by the method described below was added into the mixture, stirred and dissolved, and an epoxy resin varnish including an initiator was manufactured. This epoxy resin varnish was coated by a die coater onto the polymer precursor layer of the above-mentioned polymer precursor layer film, such that a thickness after drying would be 70 μm, dried at 80° C. to 120° C., and an insulating resin composition film was obtained.

Then, as a protective layer, a 20-μm polypropylene film was disposed, the insulator layer and the polymer precursor layer were formed by coating on the support, and a laminate for a printed wiring board 1 of the present invention, of which a surface was covered with the protective film, was obtained.

(Synthesis of Polymerization Initiation Polymer P)

30 g of propylene glycol monomethyl ether (MFG) was added to a 300 mL triple-neck flask and heated to 75° C. Into this, a solution of 8.1 g of [2-(acryloyloxy)ethyl](4-benzoylbenzyl)dimethyl ammonium bromide, 9.9 g of 2-hydroxyethylmethaacrylate, 13.5 g of isopropylmethaacrylate, 0.43 g of dimethyl-2,2′-azo bis(2-methyl propionate) and 30 g of MFG was dropped in over 2.5 hours. Then, the reaction temperature was raised to 80° C., reaction was allowed for a further 2 hours, and a polymer P with a polymerization initiation group was obtained.

### EXAMPLE 2

### Example 2

### Epoxy Insulator Layer Containing Initiator

5 g of liquid bisphenol A-type epoxy resin (epoxy equivalent 176, EPICOAT 825, made by Japan Epoxy Resins Co., Ltd.), 2 g of a phenol novolac resin including a triazine structure (PHENOLITE LA-7052, made by Dainippon Ink and Chemicals, Incorporated, non-volatile portion 62%, phenolic hydroxyl group equivalent of non-volatile portion 120) and 10.7 g of a phenoxy resin MEK varnish (YP-50EK35, made by Tohto Kasei Co., Ltd., non-volatile portion 35%), and as a polymerization initiator, 2.3 g of 1-(4-(2-hydroxyethoxy)phenyl)-2-hydroxy-2-methylpropan-1-one, 5.3 g of MEK and 0.053 g of 2-ethyl-4-methyl imidazole were mixed and stirred and completely dissolved to manufacture a varnish-form epoxy resin insulator. This epoxy resin varnish was coated by a die coater onto the polymer precursor layer of the above-mentioned polymer precursor layer film, such that a thickness after drying would be 90 μm, dried at 80° C. to 120° C., and an insulating resin composition film was obtained.

Then, as a protective layer, a 20-μm polypropylene film was disposed, the insulator layer and the polymer precursor layer were formed by coating on the support, and a laminate for a printed wiring board 2 of the present invention, of which a surface was covered with the protective layer, was obtained.

### EXAMPLE 3

### Example 3

### Epoxy Insulator Layer Containing Initiator and Double Bond Polymerizable Compound

70 parts (parts by weight, and the same hereafter) of a phthalic acid anhydride-modified novolac-type epoxy acrylate with acid value 73 (using PCR-1050 (trade name), made by Nippon Kayaku Co., Ltd.), 20 parts of acrilonitrile butadiene rubber (using PNR-1H (trade name), made by JSR Corporation), 3 parts of alkyl phenol resin (using HITANOL 2400 (trade name), made by Hitachi Chemical Co., Ltd.), 7 parts of a radical-type photopolymerizable initiator (using IRGACURE 651 (trade name), made by Nihon Ciba-Geigy K.K.), 10 parts of aluminium hydroxide (using HIGILITE H-42M (trade name), made by Showa Denko K.K.) and 40 parts of methylethyl ketone were mixed and an insulating film formation material was prepared.

A varnish of this insulating film formation material was coated by a die coater onto the polymer precursor layer of the above-mentioned polymer precursor layer film, such that a thickness after drying would be 50 μm, dried at 80° C. to 120° C., and an insulating resin composition film was obtained.

Then, as a protective layer, a 20-μm polypropylene film was disposed, the insulator layer and the polymer precursor layer were formed by coating on the support, and a laminate for a printed wiring board 3 of the present invention, of which a surface was covered with the protective layer, was obtained.

### EXAMPLE 4

### Example 4

### Phenoxy Ether Insulator Layer Containing Initiator

In 183 g of toluene, 50 g of polyphenylene ether resin (PKN4752, trade name made by Nippon GE Plastics K.K.), 100 g of 2,2-bis(4-cyanato phenyl)propane (AROCYB-10, trade name made by Asahi Ciba Ltd.), 28.1 g of 9,10-dihydro-9-oxa-10-phosphaphenantolene-10-oxide (HCA-HQ, trade name made by Sanko Chemical Industry Co., Ltd.), 0.1 g of a 17% toluene dilute solution of manganese naphthenate (Mn content=6% by weight, made by Nihon Kagaku Sangyo Co., Ltd.) and 88.3 g of 2,2-bis(4-glycidylphenyl)propane (DER331L, trade name, made by Dow Chemical Japan Ltd.) were added, and 3.3 g of 1-(4-(2-hydroxyethoxy)phenyl)-2-hydroxy-2-methylpropan-1-one was further added as a polymerization initiator, heated and dissolved at 80° C., and a coating liquid was prepared. This material resin coating liquid was coated by a die coater onto the polymer precursor layer of the above-mentioned polymer precursor layer film, such that a thickness after drying would be 50 μm, dried at 80° C. to 120° C., and an insulating resin composition film was obtained.

Then, as a protective layer, a 20-μm polypropylene film was disposed, the insulator layer and the polymer precursor layer were formed by coating on the support, and a laminate for a printed wiring board 4 of the present invention, of which a surface was covered with the protective layer, was obtained.

### EXAMPLE 5

### Example 5

### Polyether Sulfone Insulator Layer Containing Initiator

70 parts by weight of a 25% acrylic modified compound of a cresol novolac-type epoxy resin (made by Nippon Kayaku Co., Ltd., molecular weight 2500) dissolved in diethylene glycoldimethyl ether, 30 parts by weight of polyether sulfone, 4 parts by weight of an imidazole-based curing agent (made by Shikoku Chemicals Corporation, trade name 2E4MZ-CN), 10 parts by weight of caprolactone tris(acroyloxy)isocyanurate (made by Toagosei Co., Ltd., trade name ARONIX M325), 5 parts by weight of benzophenone (Tokyo Chemical Industry Co., Ltd.), 0.5 parts by weight of Michler's ketone (Tokyo Chemical Industry Co., Ltd.) and 20 parts by weight of epoxy resin particles with average diameter 0.5μ were mixed. This mixed insulating film formation material resin coating liquid was coated by a die coater onto the polymer precursor layer of the above-mentioned polymer precursor layer film, such that a thickness after drying would be 70 μm, dried at 80° C. to 120° C., and an insulating resin composition film was obtained.

Then, as a protective layer, a 20-μm polypropylene film was disposed, the insulator layer and the polymer precursor layer were formed by coating on the support, and a laminate for a printed wiring board 5 of the present invention, of which a surface was covered with the protective layer, was obtained.

(Manufacture of a Printed Wiring Board Using the Laminate for a Printed Wiring Board)

(1-1) Application of the Laminate for a Printed Wiring Board on a Substrate

Of the films of laminates for a printed wiring board obtained as described above, using the laminate films 1-5, the protective film was peeled off and the film of the laminate for the printed wiring board was disposed on a substrate on which wiring was to be formed (a pattern-processed glass epoxy inner layer circuit substrate (conductor thickness 18 μm)), such that the substrate and the insulating film were laminated, and they were caused to adhere by a vacuum laminator under conditions of 0.2 MPa pressure and 100° C. to 110° C.

(2-1) Exposure (Formation of Graft Polymer)

Next, the support of the laminate 1-5 was peeled off, the whole surface was exposed by the method described below, washing processing was performed, and a surface graft material in which a polymer graft was formed on the insulator composition layer was obtained.

For exposure, light was exposed for 1 minute at room temperature using an exposure unit: an ultraviolet ray irradiation device (UVX-02516S1LP01, made by Ushio Inc.). After exposure, thorough washing with pure water was performed.

(Manufacture of a Printed Wiring Board Using the Laminate for a Printed Wiring Board)

(3-2) Adherence of Conductive Material and Verification Thereof

To the surface graft pattern materials 1-5 of the present invention obtained as described above, respectively, a conductive substance was applied by, of the two methods described below, the method described in the below table 1, and wiring boards of Examples 1-5 were obtained.

—Conductive Adhesion Method A: Implementation of Electroless Plating and Electroplating Steps—

The surface graft material 1-3 was immersed for 1 hour in an aqueous solution with 0.1% by weight of silver nitrate (Wako Pure Chemical Industries, Ltd.), and then washed with distilled water. Then, it was immersed for 10 minutes in an electroless plating bath of the following composition, and then electroplated for 20 minutes in an electrode plating bath of the below composition, and conductive pattern materials of Examples 2 to 4 were manufactured.

<Electroless Plating Bath Composition>

Copper sulfate 0.3 g

NaK tartrate 1.7 g

Sodium hydroxide 0.7 g

Formaldehyde 0.2 g

Water 48 g

<Electroplating Bath Composition>

Copper sulfate 38 g

Sulfuric acid 95 g

Hydrochloric acid 1 mL

COPPERGLEAM PCM (made by Meltex Inc.) 3 mL

Water 500 g

(Conductive Adhesion Method B: Implementation of Steps of Adhesion of Conductive Particles and Electroless Plating Processing)

The formed graft polymer material 4-5 was immersed for 1 hour in a liquid in which Ag particles with positive charges were dispersed, manufactured by the following procedure, and then washed with distilled water. Thereafter, by a plating process the same as in conductive method A, coppered laminates (conductive materials) of Examples 4 and 5 were manufactured.

<Synthesis Procedure of Ag Particles with Positive Charges>

3 g of bis(1,1-trimethyl ammonium decanoylaminoethyl)disulfide was added to (5 mM) 50 mL of an ethanol solution of silver perchlorate. This was vigorously stirred while (0.4 M) 30 mL of a sodium boron hydride solution was slowly dropped in, the ions were reduced, and a dispersion of silver particles covered with quaternary ammonium was obtained.

—Evaluation of Conductive Pattern Materials—

(Surface Unevenness)

Surface unevenness of the obtained conductive materials was measured with a NANOPICS (NANOPICS 1000, made by Seiko Instruments Inc., using a DFM cantilever). Results are shown in the following table 1.

(Measurement of Metal Film Thickness)

This was measured with use of a DFM cantilever.

(Adhesive Strength Evaluation)

A copper plate (thickness 50 μm) was adhered to the conductive material surface at which the metal film was formed with an epoxy-based adhesive (ARALDITE, made by Ciba-Geigy). This was heated for 4 hours at 140° C., and then a 90° stripping test based on JIS C 6481 was performed. For a stripping device, a tension tester AGS-J, made by Shimadzu Corporation, was employed. Results are shown in the following table 1.

TABLE 1

| | | | | Conductive | |
|---|---|---|---|---|---|
| | | | | material | |
| | | Surface | Conductor | surface | Adhesive |
| | | graft | adhesion | unevenness | strength |
| | Laminate | material | method | (Rz, nm) | (kN/m) |
| Example 1 | 1 | 1 | A | 450 | 0.8 |
| Example 2 | 2 | 2 | A | 600 | 1.0 |
| Example 3 | 3 | 3 | A | 750 | 0.8 |
| Example 4 | 4 | 4 | B | 670 | 0.9 |
| Example 5 | 5 | 5 | B | 800 | 0.8 |

As is clear in table 1, it was found that in a conductive material obtained by the manufacturing process of the present invention, a metal film with sufficient thickness and excellent adhesion to a substrate is formed at a smooth insulator layer surface with small surface unevenness.

5. Formation of Pattern

Using the conductive materials (copper substrates) obtained by Examples 1 to 5, fine wiring was manufactured.

A photocurable photosensitive dry film (made by Fujifilm Corporation) was laminated onto the surface of the above conductive material (Examples 1-5). Ultraviolet exposure was performed through a mask film in which a desired conductive circuit pattern had been imaged (a metal pattern portion being an open portion and a metal pattern non-formation portion being a mask portion), an image was printed, and development was performed. Then, using a cupric chloride etching fluid, the metal film (copper thin film) was removed at portions from which the resist had been removed. Thereafter, by stripping the dry film, a copper fine pattern was obtained. Formation of the pattern was measured.

The conductive patterns that were formed were evaluated as follows.

(Pattern Formation Characteristics)

Using an optical microscope (OPTI PHOTO-2, made by Nikon Corporation), fine wire widths were measured. Results are shown in the following table 2.

(Surface Unevenness)

Surface unevennesses of the obtained conductive materials were measured with a NANOPICS (NANOPICS 1000, made by Seiko Instruments Inc., using a DFM cantilever). Results are shown in the following table 2.

(Adhesive Strength Evaluation)

A copper plate (thickness 50 μm) was adhered to the surface of the metal pattern (width 50 μm) with an epoxy-based adhesive (ARALDITE, made by Ciba-Geigy). This was heated for 4 hours at 140° C., and then a 90° stripping test based on JIS C 6481 was performed. For a stripping device, a tension tester AGS-J, made by Shimadzu Corporation, was employed. Results are shown in the following table 2.

TABLE 2

| | Lines/spaces | Substrate surface | Adhesive |
|---|---|---|---|
| | (μm) | unevenness (Rz, nm) | strength (kN/m) |
| Example 1 | 20/20 | 400 | 0.7 |
| Example 2 | 15/15 | 650 | 0.9 |
| Example 3 | 25/25 | 700 | 0.8 |
| Example 4 | 21/22 | 750 | 0.9 |
| Example 5 | 15/15 | 600 | 0.8 |

As is clear in table 2, it was found that when forming a conductive pattern using a conductive material of the present invention, fine wiring with high adhesiveness to a substrate can be formed at a smooth insulator layer surface with small substrate surface unevenness.

### EXAMPLE 6

### Manufacture of Laminate For a Printed Wiring Board

Using a thickness 20 μm polyethylene terephthalate resin sheet as a support, a polymer precursor layer (A) was formed so as to have a thickness of 0.5 to 1.5 μm, in the same manner as the in the Examples 1 to 5. For the polymer precursor layer, a coating liquid composition was coated onto the support surface by a roller coater, and then dried for 10 minutes at 80 to 100° C. to be manufactured. Then, the insulating resin composition used in Example 1 was coated by a roller coater, dried for 10 minutes at 80 to 100° C., and an insulating film was formed such that a thickness would be 50 μm, and a laminate for a printed wiring board with a surface covered with a protective film (a thickness 20 μm PP film) was obtained.

(Formation of Printed Wiring Board)

A glass epoxy inner layer circuit substrate was prepared as an inner layer substrate, and the laminate for a printed wiring board was laminated at both sides simultaneously by a vacuum laminator while the protective film was peeled off.

Lamination conditions were as follows.

Continuous system: roller temperature 100° C., pressure 3 kgf/cm², speed 30 cm/minute

Air pressure 30 mmHg or less

Batch system: roller temperature 80° C., pressure 1 kgf/cm², 5 second pressing

Air pressure 2 mmHg or less

After lamination was completed, it was left until room temperature, and the support (base film) was peeled off.

A pre-heating treatment was performed for 30 minutes at 170° C.

Next, hole formation of opening portions with diameter 100 μm was implemented by a CO₂ laser at via hole portions. Then, UV light at 254 nm was irradiated for 40 seconds at a region at which a wiring pattern was to be formed, and the graft polymer was produced at irradiated portions. Thereafter, washing was performed for 5 minutes and the unreacted polymer precursor compound and the like was removed.

The resin was swollen for 60 minutes at 75° C. with a swelling agent (CIRCUPOSIT 211 and CIRCUPOSIT Z (Rohm and Haas Company)), then washed, and immersed in a liquid in which a plating catalyst (a 1% silver nitrate solution) was dispersed. The plating catalyst was applied to the graft polymer and then the conductive layer was formed by electroless plating, and a printed wiring pattern was formed.

Thereafter, in order to stabilize adhesive strength of the conductor, an annealing treatment was performed for 60 minutes at 150° C.

When the surface was inspected, it was confirmed that the fine conductive layer with width 20 μm was formed only at the exposed region. When conductivity of the conductive layer that had been formed was checked, conduction was confirmed.

### EXAMPLE 7

### Manufacture of Laminate For a Printed Wiring Board

Using a thickness 16 μm polyethylene terephthalate resin film as a support, a polymer precursor layer (A) and insulating resin composition layer (B) were formed in the same manner as in Example 1. Then, as a protective layer, a 20-μm polypropylene film was disposed, and a laminate for a printed wiring board 7 of the present invention was obtained.

(Manufacture of Printed Wiring Board Using Laminate for a Printed Wiring Board)

(1) Application of Laminate For a Printed Wiring Board on Substrate

Using the film of the laminate for a printed wiring board 7 obtained as described above, the protective film was peeled off and the film of the laminate for a printed wiring board was disposed on a substrate on which wiring was to be formed (a pattern-processed glass epoxy inner layer circuit substrate (conductor thickness 18 μm)), such that the substrate and the insulating film were laminated, and they were caused to adhere by a vacuum laminator under conditions of 0.2 MPa pressure and 100° C. to 110° C.

(2) Exposure (Formation of Graft Polymer)

Next, the support of the laminate 7 was peeled off, the whole surface was exposed by the method described below, washing processing was performed, and a surface graft material in which a polymer graft was formed on the insulator composition layer was obtained.

For exposure, light was exposed for 1 minute at room temperature using an exposure unit: an ultraviolet ray irradiation device (UVX-02516S1LP01, made by Ushio Inc.). After exposure, thorough washing with pure water was performed.

(Manufacture of Printed Wiring Board Using Laminate For a Printed Wiring Board)

(3) Adherence of Conductive Material and Verification Thereof

The surface graft material 6 obtained as described above was immersed for 1 hour in an aqueous solution with 0.1% by weight of silver nitrate (Wako Pure Chemical Industries, Ltd.), and then washed with distilled water. Then, it was immersed for 10 minutes in an electroless plating bath the same as that used for Example 1, and then electroplated for 20 minutes in an electroplating bath of the below composition, and a conductive material of Example 7 was manufactured.

(4) Formation of Pattern

Using the conductive material (copper substrate) obtained by Example 7, fine wiring was manufactured.

A photosensitive dry film photocurable photosensitive dry film (made by Fujifilm Corporation) was laminated onto the surface of the above conductive material (Example 7). Ultraviolet exposure was performed through a mask film in which a desired conductive circuit pattern had been imaged (a metal pattern portion being an mask portion and a metal pattern non-formation portion being a open portion), an image was printed, and development was performed. Then, at a portion from which resist was removed, plating was performed for 20 minutes in an electroplating bath the same as that used in Example 1. Then, after the dry film resist was stripped off, the metal film (copper thin film) was removed at metal pattern non-formation portions using a cupric chloride etching fluid, and a copper fine pattern was obtained.

When the surface was inspected, it was confirmed that the fine conductive layer with width 20 μm was formed only at the exposed region. When conductivity of the conductive layer that had been formed was checked, conduction was confirmed.

All the documents, patent applications and technical specifications described in the present specification are incorporated into the present specification by reference, to the same extent as if the individual documents, patent applications and technical specifications were specifically and individually described as being incorporated by reference.

### EXPLANATION OF REFERENCE NUMERALS

10 Laminate for a printed wiring board (laminate)
12 Support
14 Polymer precursor layer
16 Insulating resin composition layer
18 Protective layer
20 Inner layer circuit substrate

1. A laminate comprising, on a support:
an insulating resin composition layer configured to produce a reactive active species when provided with energy; and
a reactive polymer precursor layer containing a compound configured to react with the insulating resin composition layer and form a polymer compound.

2. A laminate for a printed wiring board according to claim 1, comprising the reactive polymer precursor layer and the insulating resin composition layer in this order on the support, and which is used for manufacturing a printed wiring board.

3. A laminate for a printed wiring board according to claim 1, comprising the insulating resin composition layer and the reactive polymer precursor layer in this order on the support, and which is used for manufacturing a printed wiring board.

4. A laminate for a printed wiring board according to claim 1, comprising, at a surface of the laminate, a protective film that serves as a protective layer, and which may be used for manufacturing a printed wiring board.

5. The laminate according to claim 1, wherein the reactive polymer precursor layer contains a compound with a functional group configured to react with the active species produced in the insulating resin composition layer and form a chemical bond when provided with energy, and which may be used for manufacturing a printed wiring board.

6. The laminate according to claim 1, wherein the insulating resin composition layer contains a compound with a functional group configured to react with the reactive polymer precursor layer and form a chemical bond when provided with energy, and which may be used for manufacturing a printed wiring board.

7. The laminate according to claim 1, wherein the reactive polymer precursor layer contains a compound with a polymerizable double bond, and which may be used for manufacturing a printed wiring board.

8. A laminate for a printed wiring board according to claim 7, wherein the insulating resin composition layer contains a compound configured to produce an active species that is configured to react with the compound with a polymerizable double bond contained in the reactive polymer precursor layer, when provided with energy.

9. A method for manufacturing a printed wiring board, the method comprising:
using the laminate according to claim 1 and laminating such that the insulating resin composition layer and the reactive polymer precursor layer are disposed in this order on a substrate;
thereafter, providing energy and thereby producing a polymer compound that directly bonds with the insulating resin composition layer and forming a polymer production region; and
adhering a conductive material to the polymer production region.

10. A printed wiring board formed by:
using the laminate according to claim 1 and laminating such that the insulating resin composition layer and the reactive polymer precursor layer are disposed in this order on a substrate;
thereafter, providing energy and thereby producing a polymer compound that directly bonds with the insulating resin composition layer and forming a polymer production region; and
adhering a conductive material to the polymer production region.

11. A method for manufacturing a printed wiring board comprising:
using the laminate according to claim 1 and laminating such that the insulating resin composition layer and the reactive polymer precursor layer are disposed in this order on a substrate;
providing energy and producing a graft polymer layer that directly bonds with the insulating resin composition layer; and
adhering a conductive material to a region of production of the graft polymer.

12. A printed wiring board formed by:
using the laminate for a printed wiring board according to claim 1 and laminating such that the insulating resin composition layer and the reactive polymer precursor layer are disposed in this order on a substrate;
thereafter, providing energy and producing a graft polymer layer that adheres with the insulating resin composition layer; and
adhering a conductive material to a region of production of the graft polymer.

13. A method for manufacturing a printed wiring board, comprising:
using the laminate for a printed wiring board according to claim 1 and laminating such that the insulating resin composition layer and the reactive polymer precursor layer are disposed in this order on a substrate;
providing energy in a circuit pattern form and producing a graft polymer layer that directly bonds with the insulating resin composition layer in the circuit pattern form; and
adhering a conductive material to a region of production of the graft polymer and creating a direct circuit pattern.

14. A printed wiring board comprising a circuit pattern provided by:
using the laminate according to claim 1 and laminating such that the insulating resin composition layer and the reactive polymer precursor layer are disposed in this order on a substrate;
thereafter, providing energy in a circuit pattern form and producing a graft polymer layer that directly bonds with the insulating resin composition layer in the circuit pattern form; and
adhering a conductive material to a region of production of the graft polymer.

15. An electrical component, electronic component and electrical device employing, as a portion of a circuit, a printed wiring board manufactured by the method according to claim 9, using a laminate that comprises, on a support:
an insulating resin composition layer configured to produce a reactive active species when provided with energy; and
a reactive polymer precursor layer containing a compound configured to react with the insulating resin composition layer and form a polymer compound.

16. An electrical component, electronic component and electrical device employing, as a portion of a circuit, a printed wiring board manufactured by the method according to claim 11, using a laminate that comprises, on a support:
an insulating resin composition layer configured to produce a reactive active species when provided with energy; and
a reactive polymer precursor layer containing a compound configured to react with the insulating resin composition layer and form a polymer compound.

17. An electrical component, electronic component and electrical device employing, as a portion of a circuit, a printed wiring board manufactured by the method according to claim 13, using a laminate that comprises, on a support:
an insulating resin composition layer configured to produce a reactive active species when provided with energy; and
a reactive polymer precursor layer containing a compound configured to react with the insulating resin composition layer and form a polymer compound.
